(19) United States
(12) Patent Application Publication
(10) Pub. No.: US 2012/0256326 A1
(43) Pub. Date: Oct. 11, 2012

(54) ADHESIVE COMPOSITION, SEMICONDUCTOR DEVICE MAKING USE THEREOF, AND PRODUCTION METHOD THEREOF

(76) Inventors: Kazuyuki Mitsukura, Tsukuba-shi (JP); Takashi Kawamori, Tsukuba-shi (JP); Takashi Masuko, Tsukuba-shi (JP); Shigeki Katogi, Tsukuba-shi (JP)

(21) Appl. No.: 13/509,355

(22) PCT Filed: Nov. 10, 2010
(86) PCT No.: PCT/JP2010/070016

§ 371 Date: Jun. 22, 2012

(30) Foreign Application Priority Data
Nov. 13, 2009 (JP) 2009-260410

(51) Int. Cl. C09J 163/00; H01L 29/02; C09J 163/02; H01L 21/50

(52) U.S. Cl. 257/798; 438/118; 438/107; 522/46; 257/E21.499; 257/E29.002

(57) ABSTRACT

Disclosed is an adhesive composition used for adhesion of a semiconductor chip which contains a radiation polymerizable compound, a photoinitiator, and a thermosetting resin. When the adhesive composition forming an adhesive layer is brought to a B-stage by irradiation with light, the surface of the adhesive layer has a tack force of 200 gf/cm² or less at 30° C. and 200 gf/cm² or more at 120° C.

### TECHNICAL FIELD

The present invention relates to an adhesive composition, a semiconductor device making use thereof, and a production method thereof.

### BACKGROUND ART

A stack package type semiconductor device including a plurality of chips stacked in multiple layers is used for a memory or the like. When a semiconductor device is manufactured, a film-shaped adhesive is applied to cause semiconductor elements to adhere to each other or to cause a semiconductor element to adhere to a supporting member for mounting the semiconductor element. In recent years, as the size and height of electronic components have been reduced, it is required to further reduce the film thickness of the film-shaped adhesive for semiconductor. However, if projections and recesses resulting from wiring or the like are present on the semiconductor element or the supporting member for mounting the semiconductor element, especially when a film-shaped adhesive having a thin film thickness reduced to about 10 μm or less is used, voids tend to be produced at the time of adhesion of the adhesive to an adherend, with the result that the reliability is decreased. Since it is difficult to manufacture the film-shaped adhesive having a thickness of 10 μm or less itself, and, in the film having the reduced film thickness, the sticking property or the thermal-compression-bonding property to a wafer is degraded, it is difficult to produce a semiconductor device using it.

In order to solve these problems, for example, as in Patent Literature 1, there has been examined a method of applying an adhesive composition (resin paste) containing a solvent to an adherend to bring the applied resin paste to a B-stage by heat drying.

### CITATION LIST

### Patent Literature

Patent Literature 1
Japanese Patent Laid-Open No. 2007-110099

### SUMMARY OF INVENTION

### Technical Problem

However, when the resin paste containing a solvent is used, there are problems in which a long period is needed for volatilizing the solvent to bring it to a B-stage and a semiconductor wafer becomes contaminated with the solvent. In addition, there have been problems in which an adhesive tape cannot be easily peeled when the resin paste is applied to a wafer with the adhesive tape capable of being peeled, and in which the wafer is warped, due to heating for drying for volatilizing the solvent. When the resin paste is dried at low temperatures, the defects due to the heating can be suppressed to some extent, but in this case, voids and/or peeling tended to be caused at the time of heat curing and reliability is deteriorated, because of increasing the amount of a residual solvent. When a low-boiling solvent is used for the purpose of decreasing drying temperature, viscosity tends to greatly vary during its use. Furthermore, since a solvent remained in an adhesive layer due to proceeding volatilization of a solvent on an adhesive surface at the time of drying, there has been also a tendency in which reliability is lowered.

The present invention has been made in consideration of such circumstances as described above and is aimed mainly at providing an adhesive composition that enables further thinning of the layer of an adhesive for adhesion of a semiconductor chip to a supporting member or another semiconductor chip, while maintaining the high reliability of a semiconductor device.

### Solution to Problem

The present invention relates to an adhesive composition used for adhesion of a semiconductor chip, comprising a radiation polymerizable compound, a photoinitiator, and a thermosetting resin. When the adhesive composition forming an adhesive layer is brought to a B-stage by irradiation with light, the surface of the adhesive layer has a tack force of 200 gf/cm² or less at 30° C. and 200 gf/cm² or more at 120° C.

The adhesive composition according to the present invention includes the above-described configuration to enable further thinning of the layer of an adhesive for adhesion of a semiconductor chip to a supporting member or another semiconductor chip, while maintaining the high reliability of a semiconductor device. Particularly, the tack force of the surface of the adhesive layer of 200 gf/cm² or less at 30° C. causes good handling characteristics after being brought to a B-stage and prevents the occurrence of problems in which water enters into the interface between an adhesive and an adherend at the time of dicing to cause chip flying, the property of peeling from a dicing sheet after the dicing is lowered, and thus a pickup property is deteriorated. In addition, the tack force of 200 gf/cm² or more at 120° C. offers a good thermal compression bonding property, and can avoid problems in which voids are generated at the time of thermal compression bonding and a thermal compression bonding temperature becomes high, to thereby maintain the high reliability of a semiconductor device.

The 5% weight reduction temperature of the adhesive composition brought to a B-stage by irradiation with light is preferably 150° C. or more.

The viscosity of the adhesive composition at 25° C. before being brought to a B-stage by irradiation with light is preferably 10-30000 mPa·s.

When a semiconductor chip is made to adhere to an adherend with the adhesive composition, shear strength between the semiconductor chip and the adherend is preferably 0.2 MPa or more at 260° C.

The 5% weight reduction temperature of the adhesive composition which is brought to a B-stage by irradiation with light and then further cured by heating is preferably 260° C. or more.

The radiation polymerizable compound preferably contains a monofunctional (meth)acrylate. The monofunctional (meth)acrylate preferably includes a (meth)acrylate having an imido group.

The adhesive composition preferably contains a compound having an imido group. The compound having an imido group can be a thermoplastic resin such as a polyimide resin or a low molecular weight compound such as a (meth)acrylate having an imido group.

In another aspect, the present invention relates to a method for producing a semiconductor device. The production method according to the present invention includes the steps of: applying the adhesive composition according to the present invention to the back surface of a semiconductor wafer; bringing the applied adhesive composition to a B-stage by irradiation with light; cutting the semiconductor wafer together with the adhesive composition brought to the B-stage into a plurality of semiconductor chips; and making a semiconductor chip to adhere to a supporting member or another semiconductor chip by performing compression bonding, with the adhesive composition therebetween.

The present invention also relates to a semiconductor device which is obtainable by the production method according to the present invention. The semiconductor device according to the present invention has sufficiently high reliability even when the layer of an adhesive for adhesion of a semiconductor chip to a supporting member or another semiconductor chip is thin.

### Advantageous Effects of Invention

According to the present invention, a semiconductor device with high reliability can be produced even when the layer of an adhesive for adhesion of a semiconductor chip to a supporting member or another semiconductor chip is thinned.

### BRIEF DESCRIPTION OF DRAWINGS

FIG. 1 A schematic view showing an embodiment of the method for manufacturing the semiconductor device;

FIG. 2 A schematic view showing an embodiment of the method for manufacturing the semiconductor device;

FIG. 3 A schematic view showing an embodiment of the method for manufacturing the semiconductor device;

FIG. 4 A schematic view showing an embodiment of the method for manufacturing the semiconductor device;

FIG. 5 A schematic view showing an embodiment of the method for manufacturing the semiconductor device;

FIG. 6 A schematic view showing an embodiment of the method for manufacturing the semiconductor device;

FIG. 7 A schematic view showing an embodiment of the method for manufacturing the semiconductor device;

FIG. 8 A schematic view showing an embodiment of the method for manufacturing the semiconductor device;

FIG. 9 A schematic view showing an embodiment of the method for manufacturing the semiconductor device;

FIG. 10 A schematic view showing an embodiment of the method for manufacturing the semiconductor device;

FIG. 11 A schematic view showing an embodiment of the method for manufacturing the semiconductor device; and

FIG. 12 A schematic view showing an embodiment of the method for manufacturing the semiconductor device.

### DESCRIPTION OF EMBODIMENTS

Embodiments of the present invention will be described below in detail with reference to accompanying drawings as necessary. However, the present invention is not limited to the embodiments described below. In the drawings, the same or corresponding elements are identified with the same symbols. The repeated descriptions will be omitted as appropriate. Unless otherwise specified, the positional relationship such as the top, the bottom, the left and the right is based on the positional relationship shown in the drawings. The dimensional ratio is not limited to the ratio shown in the figures.

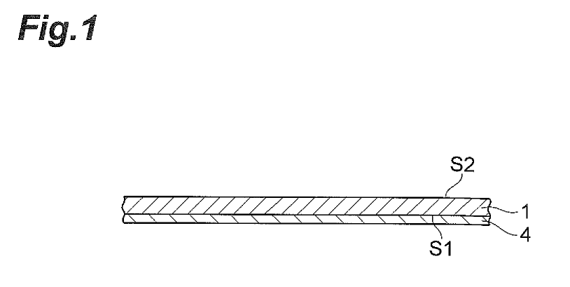

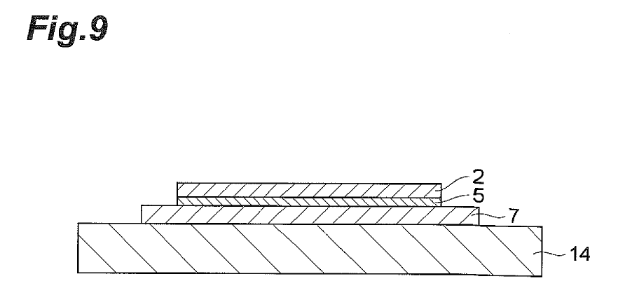

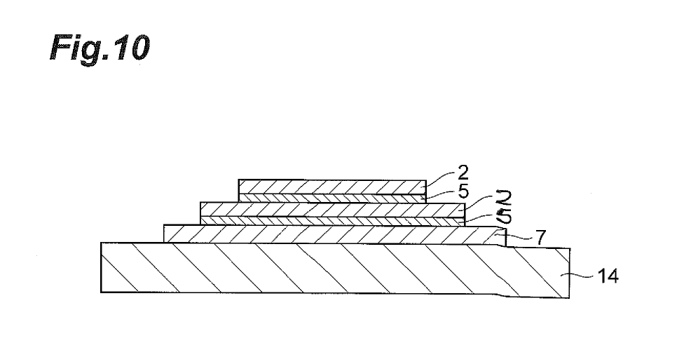

FIGS. 1 to 12 are schematic views showing an embodiment of a method for manufacturing the semiconductor device. The manufacturing method according to the present embodiment mainly includes the following steps.

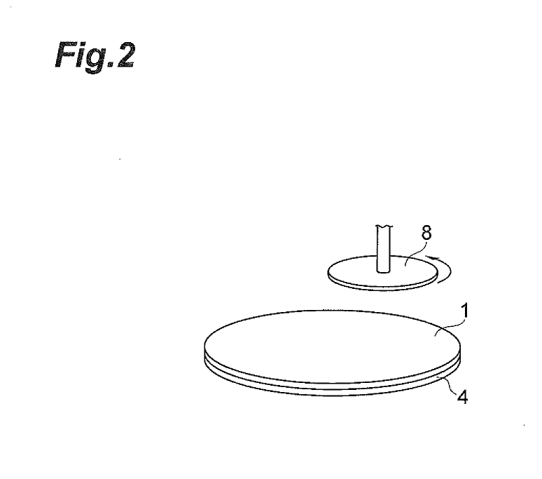

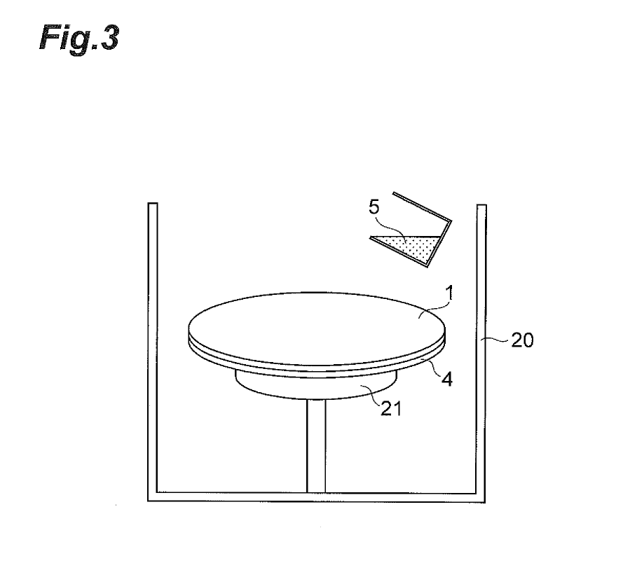

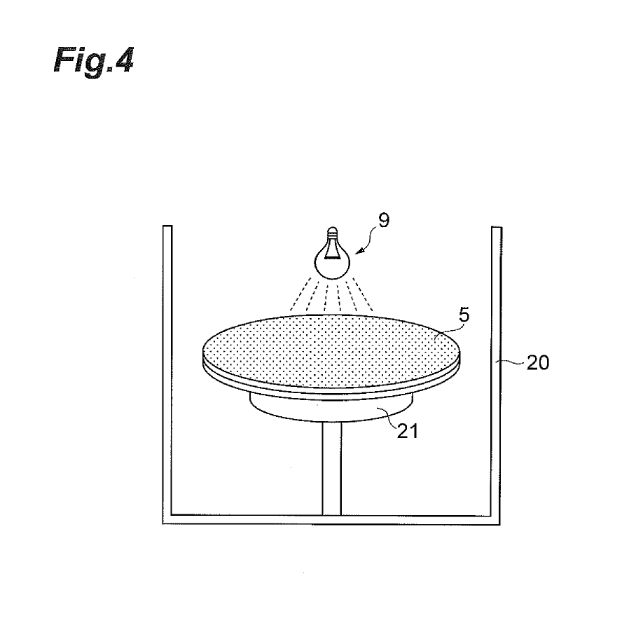

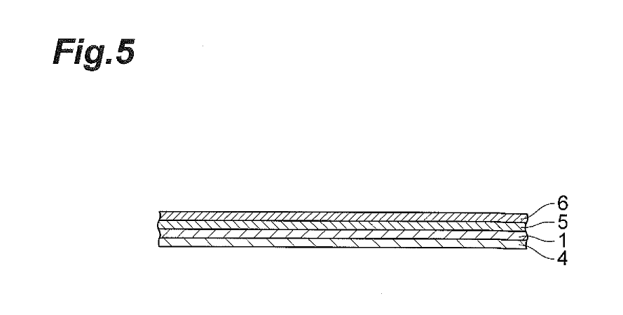

Step 1 (FIG. 1): an pressure sensitive adhesive tape (back grind tape) 4 that can be peeled off is stacked on the circuit surface S1 of the semiconductor chip (semiconductor element) 2 formed within the semiconductor wafer 1.
Step 2 (FIG. 2): the semiconductor wafer 1 is decreased in thickness by being ground from the surface (rear face) S2 opposite to the circuit surface S1 of the semiconductor wafer 1.
Step 3 (FIG. 3): the adhesive composition 5 is applied on the rear face S2 of the semiconductor wafer 1.
Step 4 (FIG. 4): the adhesive composition is B-staged by performing exposure from the side of the adhesive layer 5 that is the applied adhesive composition.
Step 5 (FIG. 5): a pressure sensitive adhesive tape (dicing tape) 6 that can be peeled off is stacked on the adhesive layer 5.

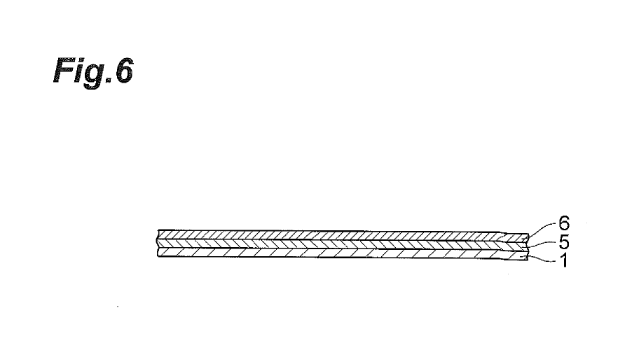

Step 6 (FIG. 6): the dicing tape 6 is peeled off.

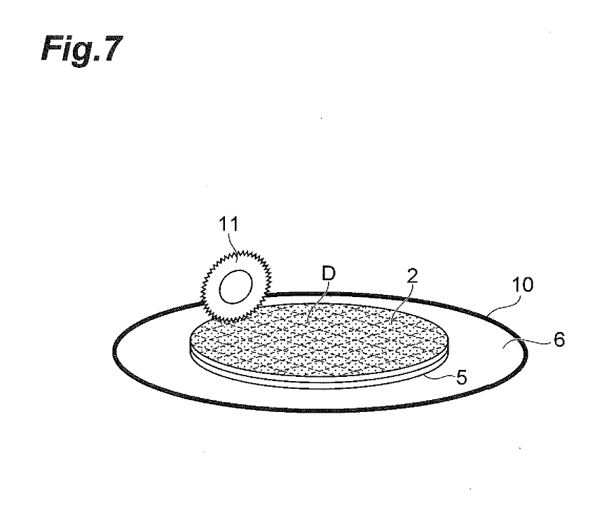

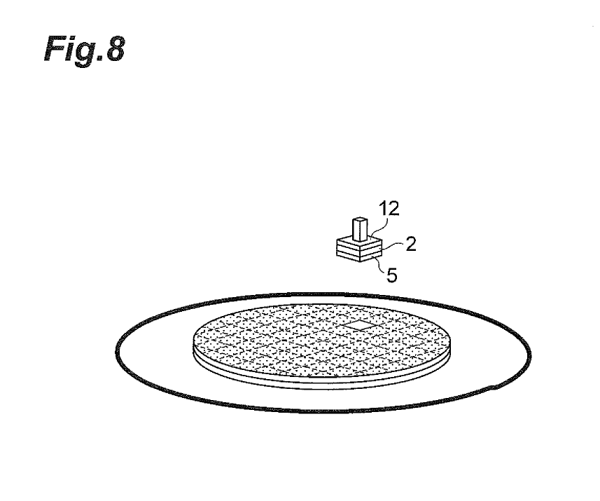

Step 7 (FIG. 7): the semiconductor wafer 1 is cut into a plurality of semiconductor chips 2 by dicing.
Step 8 (FIGS. 8, 9 and 10): the semiconductor chip 2 is picked up and compression bonded (mounted) on a semiconductor element mounting supporting member 7 or another semiconductor chip 2.

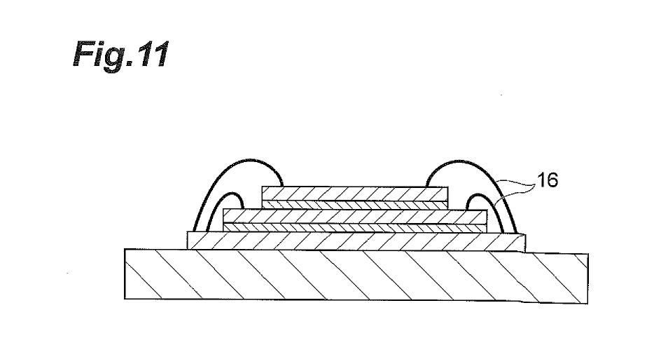

Step 9 (FIG. 11): the mounted semiconductor chip is connected to the external connection terminals on the supporting member 7 via wires 16.

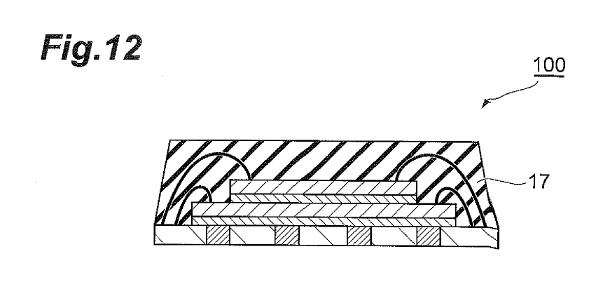

Step 10 (FIG. 12): a stacked member including a plurality of semiconductor chips 2 is sealed with the sealant 17, and thus a semiconductor device 100 is obtained.

Step 1 (FIG. 1)

The back grind tape 4 is stacked on the side of the circuit surface S1 of the semiconductor wafer 1. The stacking of the back grind tape can be performed by a method of laminating a pressure sensitive adhesive tape that is previously formed in the form of a film.

Step 2 (FIG. 2)

The surface (rear face S2) opposite to the back grind tape 4 of the semiconductor wafer 1 is ground, and thus the thickness of the semiconductor wafer 1 is reduced to a predetermined thickness. The grinding is performed using a grind device 8 with the semiconductor wafer 1 fixed to a grind jig by the back grind tape 4.

Step 3 (FIG. 3)

After the grinding, the adhesive composition 5 is applied on the rear face S2 of the semiconductor wafer 1. The applying can be performed with the semiconductor wafer 1 to which the back grind tape 4 is bonded being fixed to the jig 21 within a box 20. The applying method is selected from a printing method, a spin coat method, a spray coat method, a gap coat method, a jet dispense method, a circle coat method, an inkjet method and the like. Among them, in order to reduce the thickness of the film and uniformly form the film thickness, the spin coat method and the spray coat method are preferable. A hole may be formed in an adsorption stage included in the spin coat device; the adsorption stage may be mesh-shaped. Since an adsorption mark is unlikely to be left, the adsorption stage is preferably mesh-shaped. In order to prevent the warpage of the wafer and the rising up of an edge portion, the coating by the spin coat method is preferably performed at a rotation speed of 500 to 5000 rpm. From the same point of view, the rotation speed is further preferably 1000 to 4000 rpm. In order to adjust the viscosity of the adhesive composition, a temperature adjuster can be provided on the spin coat stage.

The adhesive composition can be stored within a syringe. In this case, the temperature adjuster may be provided in the syringe set of the spin coat device.

When the adhesive composition is applied to the semiconductor wafer by, for example, the spin coat method, an unnecessary adhesive composition may adhere to the edge portion of the semiconductor wafer. Such an unnecessary adhesive can be removed by being washed with solvent or the like after the spin coat. The washing method is not particularly limited; a method of discharging solvent from a nozzle to a portion to which the unnecessary adhesive adheres while the semiconductor wafer is being spun is preferable. The solvent used for the washing is not limited as long as is dissolves the adhesive, for example, a low boiling solvent selected from methyl ethyl ketone, acetone, isopropyl alcohol and methanol is used.

The viscosity of the applied adhesive composition at 25° C. is preferably 10-30000 mPa·s, more preferably 30-10000 mPa·s, further preferably 50-5000 mPa·s, still more preferably 100-3000 mPa·s, and most preferably 200-1000 mPa·s, from the viewpoint of a discharge property from an application device and a thin film formation property. When the above-described viscosity is 10 mPa·s or less, the storage stability of the adhesive composition tends to be decreased and pinholes in the applied adhesive composition tends to be easily generated. In addition, being brought to a B-stage by exposure tends to become difficult. When the viscosity is 30000 mPa·s or more, film thinning tends to be difficult at the time of coating and discharging tends to become difficult. A viscosity as used herein is a value measured through the use of an E-type viscometer at 25° C.

Step 4 (FIG. 4)

The adhesive composition is brought to a B-stage by irradiation with an active light beam (typically, ultraviolet ray) from the side of the adhesive layer 5 that is the applied adhesive composition, by an exposure device 9. As a result, the adhesive layer 5 is fixed on the semiconductor wafer 1 and the tack of the surface of the adhesive layer 5 can be reduced. In this stage, the semiconductor wafer with the adhesive layer according to the present embodiment is obtained. The exposure can be performed under an atmosphere such as vacuum, nitrogen, or air. In order to reduce oxygen inhibition, the exposure can also be performed in a state of layering a substrate such as a PET film, a polypropylene film, or a polyethylene film, subjected to mold-releasing treatment, on the adhesive layer 5. The exposure can also be performed via a patterned mask. Adhesive layers having different flowabilities at the time of thermal compression can be formed by using the patterned mask. A exposure level is preferably 50-2000 mJ/cm² from the viewpoint of reduction in tack and tact time.

The thickness of the adhesive layer 5 after the exposure is preferably 30 μm or less, more preferably 20 μm or less, more preferably 10 μm or less, and still more preferably 5 μm or less. From the viewpoint of a thermal compression bonding property and adhesiveness, the film thickness is preferably 1 μm or more. The film thickness of the adhesive layer 5 after the exposure can be measured, for example, by a method as described below. First, the adhesive composition is applied onto a silicon wafer by spin coating (2000 rpm/10 s, 4000 rpm/20 s). A PET film subjected to mold-releasing treatment is laminated on the obtained coating film and exposure is performed at 1000 mJ/cm² by a high-precision parallel exposure machine (manufactured by ORC Manufacturing Co., Ltd., “EXM-1172-B-∞” (trade name)). Then, the thickness of the adhesive layer is measured through the use of a surface roughness tester (manufactured by Kosaka Laboratory Ltd.).

The tack force (surface tack force) of the surface of the adhesive layer after the exposure at 30° C. is preferably 200 gf/cm² or less. As a result, from the viewpoint of handling characteristics after exposure, ease of dicing and pickup property, the adhesive layer becomes sufficiently excellent. When the tack force is 200 gf/cm² or less, it can be determined that the adhesive composition has been brought to a B-stage. The tack force of the surface of the adhesive layer at 30° C. after exposure is more preferably 150 gf/cm² or less from the viewpoint of handling characteristics and pickup property.

The tack force of the surface of the adhesive layer after exposure is measured as described below. First, the adhesive composition is applied onto a silicon wafer by spin coating (2000 rpm/10 s, 4000 rpm/20 s) and surface light release agent treatment PET (A-31) manufactured by Teij in DuPont Films Japan Limited is laminated on the applied adhesive layer at a room temperature through the use of a hand roller. Then, through the use of the high-precision parallel exposure machine (manufactured by ORC Manufacturing Co., Ltd., “EXM-1172-B-∞” (trade name)), exposure is performed at 1000 mJ/cm² from the PET side. Then, the tack force of the surface of the adhesive layer at a predetermined temperature (e.g., 30° C.) is measured through the use of a probe tacking tester manufactured by Rhesca Corporation under the conditions of probe diameter of 5.1 mm, peeling speed of 10 mm/s, contact load of 100 gf/cm², and contact time of 1 s.

When the tack force described above exceeds 200 gf/cm² at 30° C., the stickiness of the surface of the adhesive layer at room temperature becomes excessively increased and thus handing tends to be reduced. Moreover, problems tend to be easily caused in which water enters the interface between the adhesive layer and the adherend at the time of the dicing and thus chip flying occurs, and the peeling-off property from the dicing sheet after the dicing is reduced and thus the pickup property is lowered.

The tack force of the surface of the adhesive layer at 120° C. after the exposure is preferably 200 gf/cm² or more. When the tack force is less than 200 gf/cm², there are tendencies in which voids are generated during thermal compression bonding because a thermal compression bonding property is degraded, and a thermal compression bonding temperature becomes higher. The tack force of the surface of the adhesive layer after the exposure at 120° C. is more preferably 300 gf/cm² or more from the viewpoint of a low-temperature compression bonding property.

The 5% mass reduction temperature of the adhesive composition B-staged by the irradiation with light is preferably 120° C. or more, more preferably 150° C. or more, further preferably 180° C. or more, and further more preferably 200° C. or more. In order that the 5% mass reduction temperature is increased, it is preferable that the adhesive composition substantially contains no solvent. When the 5% mass reduction temperature is low, the adherend tends to be easily peeled off at the time of thermal curing after the compression bonding of the adherend or at the time of thermal history such as reflow, and thus it is necessary to perform heating and drying before the thermal compression bonding.

The 5% mass reduction temperature is measured as follows. The adhesive composition is applied onto the silicon wafer through by the spin coat (2000 rpm/10 s, 4000 rpm/20 s). The PET film subjected to mold-releasing treatment is laminated on the obtained coating film, and the exposure is performed at 1000 mJ/cm² through the use of the high precision parallel exposure device (“EXM-1172-B-∞” (trade name) manufactured by ORC Manufacturing Co., Ltd). After that, the 5% weight reduction temperature of the adhesive composition brought to a B-stage is measured through the use of the thermogravimetry differential thermal measurement device (manufactured by SII NanoTechnology Inc.: TG/DTA6300), at a temperature rise rate of 10° C./minute, under flow of nitrogen (400 ml/min).

Step 5 (FIG. 5)

After the exposure, the pressure sensitive adhesive tape 6 that can be peeled off, such as the dicing tape is stuck to the adhesive layer 5. The pressure sensitive adhesive tape 6 can be stuck by a method of laminating the pressure sensitive adhesive tape previously formed in the form of a film.

Step 6 (FIG. 6)

Then, the back grind tape 4 stuck to the circuit surface of the semiconductor wafer 1 is peeled off. For example, the adhesive tape whose stickiness is reduced by application of activated light rays (typically ultraviolet rays) is used, and the exposure is performed from the side of the back grind tape 4 and thereafter the back grind tape 4 can be peeled off.

Step 7 (FIG. 7)

Along a dicing line D, the semiconductor wafer 1 is cut together with the adhesive layer 5. By this dicing, the semiconductor wafer 1 is separated into a plurality of semiconductor chips 2 in which the adhesive layer 5 is provided on each back surface. The dicing is performed by using a dicing blade 11 with the whole semiconductor wafer fixed to a frame (wafer ring) by the pressure sensitive adhesive tape (dicing tape) 6.

Step 8 (FIGS. 8, 9 and 10)

After the dicing, the separated semiconductor chips 2 are picked up by a die bonding device 12 together with the adhesive layer 5, and are compression bonded (mounted) on the semiconductor device supporting member (supporting member for mounting the semiconductor element) 7 or another semiconductor chip 2. The compression bonding is preferably performed while being heated.

By the compression bonding, the semiconductor chips are made to adhere to the supporting member or another semiconductor chip. The shear strength at 260° C. between the semiconductor chips and the supporting member or another semiconductor chip is preferably 0.2 MPa or more, and more preferably 0.5 MPa or more. When the shear strength is less than 0.2 MPa, the peeling-off tends to be easily performed by thermal history such as a reflow step.

The shear strength here can be measured using a shearing adhesion power tester “Dage-400” (trade name). More specifically, for example, the measurement is performed by the following method. Exposure is first performed on the entire surface of the adhesive layer that is the adhesive composition applied to the semiconductor wafer, and then 3×3 square semiconductor chips are obtained by cutting. The semiconductor chips with the adhesive layer obtained by cutting are placed on a previously prepared 5×5 square semiconductor chip, and are compression bonded for two seconds at 120° C. while being pressurized at 100 gf. Thereafter, they are heated in an oven for one hour at 120° C. and then for three hours at 180° C., with the result that a sample in which the semiconductor chips are made to adhere to each other are obtained. The shear strength of the obtained sample at 260° C. is measured using the shearing adhesion power tester “Dage-400” (trade name).

Step 9 (FIG. 11)

After the step 8, each of the semiconductor chips 2 is connected to the external connection terminal on the supporting member 7 via the wire 16 connected to the bonding pad.

Step 10 (FIG. 12)

The stacked member including the semiconductor chips 2 is sealed with the sealant 17, and thus the semiconductor device 100 can be obtained.

By performing the steps described above, it is possible to manufacture the semiconductor device having a structure in which the semiconductor elements and/or the semiconductor element and the supporting member for mounting the semiconductor element are made to adhere. The structure of the semiconductor device and the method for manufacturing it are not limited to the embodiment described above; modifications are possible as appropriate without departing from the spirit of the present invention.

For example, the order of steps 1 to 7 can be changed as necessary. More specifically, the adhesive composition is applied to the back surface of the semiconductor wafer that is previously diced, and thereafter the adhesive composition can be B-staged by application of activated light rays (typically ultraviolet rays). Here, a patterned mask can be used.

Before or after the exposure, the applied adhesive composition may be heated to 120° C. or less, preferably to 100° C. or less and more preferably to 80° C. or less. In this way, the solvent and water left can be reduced, and thus it is possible to more reduce the tack after the exposure.

The 5% weight reduction temperature of the adhesive composition that has been B-staged by irradiation with light and then cured by heating is preferably 260° C. or more. When the 5% weight reduction temperature is 260° C. or less, the peeling-off tends to easily occur by the thermal history such as the reflow step.

The amount of outgassing from the adhesive composition that has been B-staged by irradiation with light and thereafter further cured by heating for one hour at 120° C. and then for three hours at 180° C. is preferably 10% or less, more preferably 7% or less and further preferably 5% or less. When the amount of outgassing is 10% or more, voids and the peeling-off tend to easily occur at the time of thermal curing.

The outgassing is measured as described below. The adhesive composition is applied onto a silicon wafer by spin coating (2000 rpm/10 s, 4000 rpm/20 s), and a PET film subjected to mold-releasing treatment is laminated on the obtained coating film through the use of a hand roller and exposure is performed at 1000 mJ/cm² by a high-precision parallel exposure machine (manufactured by ORC Manufacturing Co., Ltd., “EXM-1172-B-∞” (trade name)). Then, the amount of outgassing is measured when the adhesive composition brought to a B-stage is heated according to a program in which the temperature is raised to 120° C. at a temperature rise rate of 50° C./minute, held for one hour at 120° C., further raised to 180° C. and is then held for three hours at 180° C., under flow of nitrogen (400 ml/min) using the thermogravimetry differential thermal measurement device (manufactured by SII NanoTechnology Inc.: TG/DTA6300).

The minimum value (minimum melt viscosity) of melt viscosity (viscosity) of the adhesive composition (adhesive layer), at 20° C. to 300° C., brought to a B-stage by irradiation with light is preferably 30000 Pa·s or less.

The above-described minimum melt viscosity is more preferably 20000 Pa·s or less, further preferably 18000 Pa·s or less, particularly preferably 15000 Pa·s or less. Since the adhesive composition has the minimum melt viscosity within these ranges, the superior low-temperature heat compression bonding property of the adhesive layer can be ensured. Furthermore, good intimate contact with a substrate having recesses and projections or the like can be imparted to the adhesive layer. The minimum melt viscosity is desirably 10 Pa·s or more from the viewpoint of handling characteristics or the like.

The minimum value of the melt viscosity (the lowest melt viscosity) of the adhesive layer at temperatures of 80° C. to 200° C. is preferably 5000 Pa·s or less. Because of this, thermal fluidity at a temperature of 200° C. or less is enhanced, and thus it is possible to ensure good thermal compression bonding at the time of die bonding. In addition, the lowest melt viscosity is more preferably 3000 Pa·s or less. Therefore, when the semiconductor chip is thermal compression bonded to an adherend such as a substrate in which steps are formed on its surface at a relatively low temperature of 200° C. or less, sufficient embedding of the steps becomes further easy in the adhesive layer. The lowest melt viscosity is further preferably 1000 Pa·s or less. This makes it possible to maintain good fluidity at the time of thermal compression bonding of a thin adhesive layer. Furthermore, it is possible to perform the thermal compression bonding at a lower pressure, and this is especially advantageous when the semiconductor chip is extremely thin. The lower limit of the lowest melt viscosity is preferably 10 Pa·s or more and is more preferably 100 Pa·s or more, from the viewpoint of suppressing foaming at the time of heating. When the lowest melt viscosity exceeds 5000 Pa·s or more, lack of fluidity at the time of thermal compression bonding may prevent sufficient wettability on a supporting substrate or an adherend such as the semiconductor element from being acquired. When wettability lacks, sufficient adhesion cannot be held in the subsequent assembly of the semiconductor device, and thus the reliability of the obtained semiconductor device is more likely to be reduced. Moreover, since a high thermal compression bonding temperature is needed to ensure sufficient fluidity of the adhesive layer, thermal damage to peripheral members such as the warpage of the semiconductor element after the semiconductor element has been made to adhere and fixed tends to be increased.

The maximum value of the melt viscosity (maximum melt viscosity) of the adhesive layer brought to a B-stage at 20 to 60° C. is preferably 5000 to 100000 Pa·s. As a result, the good self-supporting property of the adhesive layer is obtained. The above-described maximum melt viscosity is more preferably 10000 Pa·s or more. As a result, the stickiness of the surface of the adhesive layer is reduced, and thus the storage stability of the semiconductor wafer with the adhesive layer is improved. The above-described maximum melt viscosity is further preferably 30000 Pa·s or more. Therefore, the hardness of the adhesive layer is increased and thus lamination with a dicing tape by pressurization is facilitated. The above-described maximum melt viscosity is further preferably 50000 Pa·s or more. Because of this, the tack strength of the surface of the adhesive layer is sufficiently decreased, and thus a good peeling property from the dicing tape after the dicing step can be ensured. When the peeling property is good, the pickup property of the semiconductor chips with the adhesive layer after the completion of the dicing step can preferably be ensured.

When the maximum melt viscosity is below 5000 Pa·s, the tack force on the surface of the adhesive layer brought to the B-stage tends to be excessively increased. Therefore, when semiconductor chips obtained by dividing the semiconductor wafer with the adhesive layer through dicing into individual pieces are picked up together with the adhesive layer, the semiconductor chips tend to be easily broken, since the peeling force of the adhesive layer from the dicing sheet is excessively high. The maximum melt viscosity is preferably 100000 Pa·s or less from the viewpoint of suppressing the warpage of the semiconductor wafer.

In the present specification, the maximum melt viscosity and the lowest melt viscosity are values measured by the following method. First, the adhesive composition is applied onto a PET film such that its film thickness is 50 μm, a PET film subjected to mold-releasing treatment is laminated on the obtained coating film through the use of a hand roller and the coating film is exposed, under the air of room temperature at 1000 mJ/cm² through the use of a high precision parallel exposure device (“EXM-1172-B-∞” (trade name) manufactured by ORC Manufacturing Co., Ltd.) and the adhesive layer brought to a B-stage is formed. The formed adhesive layer is stuck to a Teflon (registered trade mark) sheet, and is pressurized by a roll (at a temperature of 60° C., a linear pressure of 4 kgf/cm, a transfer rate of 0.5 m/minute). After that, the PET film is peeled off, and another adhesive layer brought to the B-stage by exposure is laid on the adhesive layer, and they are stacked while being pressurized. By repeating this, an adhesive sample having a thickness of about 200 μm is obtained. The melt viscosity of the obtained adhesive sample is measured, through the use of a viscoelasticity measurement device (manufactured by Rheometric Scientific F.E. Ltd., the trade name: ARES) and a parallel plate having a diameter of 25 mm as a measurement plate, under the conditions of a temperature rise rate of 10° C./minute, a frequency of 1 Hz and measurement temperatures of 20 to 200° C. or 20 to 300° C. The maximum melt viscosity at temperatures of 20 to 60° C. and the minimum melt viscosity at temperatures of 80 to 200° C. are read from the relationship between the obtained melt viscosity and the temperature.

The adhesive composition contains, for example, a photoinitiator and a radiation polymerizable compound. Preferably, the adhesive composition contains substantially no solvent.

As the photoinitiator, a compound that generates a radical, an acid, or a base by irradiation with light can be used. Among them, a compound that generates a radical and/or a base by irradiation with light are preferably used from the viewpoint of corrosion resistance such as migration and particularly, a compound that generates a radical is preferably used from the viewpoint of no need for heat treatment after exposure and high sensitivity. A compound that generates an acid or a base by irradiation with light expresses the function of accelerating polymerization and/or reaction of an epoxy resin.

The molecular extinction coefficient of the photoinitiator for light having a wavelength of 365 nm is preferably 100 ml/g·cm or more, more preferably 200 ml/g·cm or more, from the viewpoint of improvement of sensitivity. The molecular extinction coefficient is determined by preparing a 0.001 mass % acetonitrile solution of a sample and measuring the absorbance of the solution through the use of a spectrophotometer (manufactured by Hitachi High-Technologies Corporation, “U-3310” (trade name)).

Examples of such compounds that generate radicals include aromatic ketones such as 2-benzyl-2-dimethylamino-1-(4-morpholinophenyl)-butanone-1,2,2-dimethoxy-1,2-diphenylethane-1-one, 1-hydroxy-cyclohexyl-phenyl-ketone, 2-methyl-1-(4-(methylthio)phenyl)-2-morpholinopropanone-1,2,4-diethylthioxanthone, 2-ethylanthraquinone, and phenanthrenequinone; benzyl derivatives such as benzyl dimethyl ketal; 2,4,5-triarylimidazole dimers such as 2-(o-chlorophenyl)-4,5-diphenylimidazole dimer, 2-(o-chlorophenyl)-4,5-di(m-methoxyphenyl)imidazole dimer, 2-(o-fluorophenyl)-4,5-phenylimidazole dimer, 2-(o-methoxyphenyl)-4,5-diphenylimidazole dimer, 2-(p-methoxyphenyl)-4,5-diphenylimidazole dimer, 2,4-di(p-methoxyphenyl)-5-phenylimidazole dimer, and 2-(2,4-dimethoxyphenyl)-4,5-diphenylimidazole dimer; acridine derivatives such as 9-phenylacridine and 1,7-bis(9,9′-acridinyl)heptane; bisacyl phosphine oxides such as bis(2,6-dimethoxybenzoyl)-2,4,4-trimethyl-pentyl phosphine oxide and bis(2,4,6,-trimethylbenzoyl)-phenyl phosphine oxide; oxime ester-based compounds; and maleimide compounds. They may be used alone or in combination of two or more thereof.

In the above-described photoinitiators, there are preferably used 2,2-dimethoxy-1,2-diphenylethane-1-one, 2-benzyl-2-dimethylamino-1-(4-morpholinophenyl)-butanone-1,2,2-dimethoxy-1,2-diphenylethane-1-one, and 2-methyl-1-(4-(methylthio)phenyl)-2-morpholinopropane-1-one are preferably used from the viewpoint of solubility in the adhesive composition containing no solvent. In addition, from the viewpoint of being able to be brought to a B-stage by exposure even in air atmosphere, 2-benzyl-2-dimethylamino-1-(4-morpholinophenyl)-butanone-1,2,2-dimethoxy-1,2-diphenylethane-1-one, and 2-methyl-1-(4-(methylthio)phenyl)-2-morpholinopropane-1-one.

The high-temperature adhesiveness to an adherend and the moisture resistance of the adhesive composition can further be improved by using a compound that generates a base by exposure (photobase generator). This is because it is considered that a base formed from the photobase generator can efficiently act as a curing catalyst for an epoxy resin to thereby further increase a cross-linking density or that a generated curing catalyst rarely corrodes a substrate. In addition, the cross-linking density can be improved and outgassing at the time of being left at high temperatures can further be reduced by causing the adhesive composition to contain the photobase generator. Furthermore, a curing process temperature is considered to be able to be decreased to a low temperature for shorter time.

The photobase generator can be used without particular limitation if it is a compound that generates a base by radiation exposure. The generated base is preferably a strongly basic compound from the viewpoint of reactivity and curing rate. More specifically, the pKa value of the base generated by the photobase generator in an aqueous solution is preferably 7 or more, more preferably 8 or more. Generally, pKa is the logarithm of the acid dissociation constant as the index of basicity.

Examples of such bases generated by radiation exposure include imidazole derivatives such as imidazole, 2,4-dimethylimidazole, and 1-methylimidazole; piperazine derivatives such as piperazine and 2,5-dimethylpiperazine; piperidine derivatives such as piperidine and 1,2-dimethylpiperidine; trialkylamine derivatives such as trimethylamine, triethylamine, and triethanolamine; pyridine derivatives in which an amino or alkylamino group is substituted in the 4-position such as 4-methylaminopyridine, 4-dimethylaminopyridine, or the like; pyrrolidine derivatives such as pyrrolidine and n-methylpyrrolidine; alicyclic amine derivatives such as 1,8-diazabiscyclo(5,4,0)undecene-1 (DBU); benzylamine derivatives such as benzylmethylamine, benzyldimethylamine, and benzyldiethylamine; proline derivatives; triethylenediamine; morpholine derivatives; and primary alkylamines.

As the photoinitiators, there can be used oxime derivatives that generate a primary amino group by irradiation with an active light beam; 2-methyl-1-(4-(methylthio)phenyl)-2-morpholinopropane-1-one (manufactured by Ciba Specialty Chemicals, Irgacure 907), 2-benzyl-2-dimethylamino-1-(4-morpholinophenyl)-butanone-1 (manufactured by Ciba Specialty Chemicals, Irgacure 369), and 3,6-bis-(2-methyl-2-morpholino-propionyl)-9-N-octylcarbazole (manufactured by ADEKA, Optomer N-1414), which are commercially available as photo-radical generators; hexaarylbisimidazole derivatives (in which a substituent such as halogen, an alkoxy group, a nitro group, and a cyano group may be substituted by a phenyl group); benzisoxazolone derivatives; carbamate derivatives; and the like.

As the above-described photobase generators that generate bases by radiation irradiation, for example, quaternary ammonium salt derivatives can be used which are disclosed in clauses 313 and 314, volume 12 (1999), Journal of Photopolymer Science and Technology and in clauses 170 to 176 (1999), volume 11, Chemistry of Materials. Since they generate strongly basic trialkyl amine by the irradiation with active light beam, they are suitable for curing epoxy resin.

As the photobase generator, carbamic acid derivatives can also be used that is disclosed in page 12925, volume 118 (1996), Journal of American Chemical Society and in page 795, volume 28 (1996), Polymer Journal.

Examples of the photobase generator that generates a base by the application of activation rays include oxime derivatives such as 2,4-dimethoxy-1,2-diphenylethane-1-on, 1,2-octanedione, 1-[4-(phenylthio)-, 2-(o-benzoyloxime)], ethanone and 1-[9-ethyl-6-(2-methylbenzoyl)-9H-carbazol-yl]-, 1-(o-acetyloxime); 2-benzyl-2-dimethylamino-1-(4-morpholinophenyl)-butanone-1,2,2-dimethoxy-1,2-diphenylethane-1-on, 2-methyl-1-(4-(methylthio)phenyl)-2-morpholinopropan-1-on, 2-benzyl-2-dimethylamino-1-(4-morpholinophenyl)-butanone-1, hexaarylbisimidazole derivative (a substituent such as halogen, an alkoxy group, a nitro group, a cyano group may be substituted in a phenyl group) which are commercially available as a photoradical generator, a benzoisooxazolone derivative, and the like.

As the photobase generator described above, a compound in which a group for generating a base is introduced in the main chain and/or the side chain of a polymer may be used. In this case, as its molecular weight, from the viewpoint of adhesiveness, fluidity and heat resistance as the adhesive, the weight-average molecular weight thereof is preferably 1000 to 100000, and more preferably 5000 to 30000.

Since the photobase generator described above does not react with epoxy resin without exposure, it has significantly excellent storage stability at room temperature.

As an example of the radiation polymerizable compound, there is a compound that has an ethylenically unsaturated group. Examples of the ethylenically unsaturated group include a vinyl group, an allyl group, a propargylic group, a butenyl group, an ethynyl group, a phenylethynyl group, a maleimide group, a nadimide group and a (meth)acrylic group. In terms of reactivity, a (meth)acrylic group is preferable. The radiation polymerizable compound preferably contains a monofunctional (meth)acrylate. By adding the monofunctional (meth)acrylate, in particular, it is possible to reduce the cross-linking density at the time of the exposure for being brought to the B-stage, and to obtain good thermal compression bonding property, low stress and adhesion after exposure.

The 5% weight reduction temperature of the monofunctional (meth)acrylate is preferably 100° C. or more, more preferably 120° C. or more, further preferably 150° C. or more and further more preferably 180° C. or more. Here, the 5% weight reduction temperature of the radiation polymerizable compound (the monofunctional (meth)acrylate) is measured using the thermogravimetry differential thermal measurement device (manufactured by SII NanoTechnology Inc.: TG/DTA6300), at a temperature rise rate of 10° C./minute, under flow of nitrogen (400 ml/min). By using the monofunctional (meth)acrylate whose 5% weight reduction temperature is high, it is possible to reduce the volatilization of the unreacted monofunctional (meth)acrylate left after being brought to the B-stage at the time of the thermal compression bonding or the thermal curing.

The monofunctional (meth)acrylate is selected from, for example, a glycidyl group-containing (meth)acrylate, a phenol EO modified (meth)acrylate, a phenol PO-modified (meth)acrylate, a nonyl phenol EO-modified (meth)acrylate, a nonyl phenol PO-modified (meth)acrylate, a phenolic hydroxyl group-containing (meth)acrylate, a hydroxyl group-containing (meth)acrylate, an aromatic (meth)acrylate such as a phenylphenol glycidyl ether (meth)acrylate, a phenoxy ethyl (meth)acrylate and the like, an imide group-containing (meth)acrylate, a carboxyl group-containing (meth)acrylate, an isobornyl group-containing (meth)acrylate, a dicyclopentadienyl group-containing (meth)acrylate and an isobornyl (meth)acrylate.

From the viewpoint of intimate contact with the adherend after being brought to the B-stage, adhesion after the curing and heat resistance, the monofunctional (meth)acrylate preferably has at least one kind of functional group selected from a urethane group, an isocyanurate group, imide group and a hydroxyl group. In particular, the monofunctional (meth)acrylate having an imide group is preferable.

The monofunctional (meth)acrylate having an epoxy group can also be preferably used. From the viewpoint of storage stability, adhesiveness, the reduction of an outgassing and heat-resistant and moisture-resistant reliability, the 5% weight reduction temperature of the monofunctional (meth)acrylate having an epoxy group is preferably 150° C. or more, more preferably 180° C. or more and further preferably 200° C. or more. From the viewpoint of being capable of suppressing volatilization or the segregation on the surface due to heat drying at the time of film formation, the 5% weight reduction temperature of the monofunctional (meth)acrylate containing an epoxy group is preferably 150° C. or more, from the viewpoint of being capable of suppressing voids and the peeling-off resulting from an outgassing at the time of thermal curing, and the decrease in adhesiveness, the 5% weight reduction temperature is further preferably 180° C. or more and further more preferably 200° C. or more, and from the viewpoint of being capable of suppressing voids and the peeling-off due to the volatilization of an unreacted component at the time of reflow, the 5% weight reduction temperature is most preferably 260° C. or more. The monofunctional (meth)acrylate having an epoxy group preferably includes an aromatic ring. It is possible to obtain high heat resistance by using a polyfunctional epoxy resin having a 5% weight reduction temperature of 150° C. or more, as the raw material of the monofunctional (meth)acrylate.

Although the monofunctional (meth)acrylate containing an epoxy group is not particularly limited; examples thereof include glycidyl methacrylate, glycidyl acrylate, 4-hydroxybutyl acrylate glycidyl ether, 4-hydroxybutyl methacrylate glycidyl ether, and, a compound obtained by reacting a compound with a functional group that reacts with an epoxy group and an ethylenically unsaturated group, with a polyfunctional epoxy resin, and the like. The functional group that reacts with an epoxy group is not particularly limited; but examples thereof include an isocyanate group, a carboxyl group, a phenolic hydroxyl group, a hydroxyl group, an acid anhydride group, an amino group, a thiol group, an amide group and the like. These compounds can be used alone or in combination of two or more of them.

The monofunctional (meth)acrylate containing an epoxy group can be obtained, for example, by reacting a polyfunctional epoxy resin having at least two or more epoxy groups within one molecule with 0.1 to 0.9 equivalent of a (meth)acrylic acid relative to 1 equivalent of the epoxy group under the presence of triphenyl phosphine and tetrabutylammonium bromide. A glycidyl group-containing urethane (meth)acrylate or the like can be obtained by reacting a polyfunctional isocyanate compound with a hydroxy group-containing (meth)acrylate and a hydroxy group-containing epoxy compound, or reacting a polyfunctional epoxy resin with an isocyanate group-containing (meth)acrylate, under the presence of dibutyl tin dilaurate.

Furthermore, it is preferable to use, as the monofunctional (meth)acrylate containing an epoxy group, a high-purity one obtained by reducing impurity ions such as alkali metal ions, alkaline earth metal ions, halogen ions and especially chlorine ions, hydrolyzable chlorine and the like to 1000 ppm or less, in order to prevent electromigration and the corrosion of a metal conductor circuit. For example, a polyfunctional epoxy resin in which alkali metal ions, alkaline earth metal ions, halogen ions and the like are reduced is used as the raw material, and thus it is possible to satisfy the impurity ion concentration described above. All chlorine content can be measured according to JIS K7243-3.

The monofunctional (meth)acrylate component containing an epoxy group satisfying the heat resistance and the purity is not particularly limited. Examples thereof include ones that use, as their raw materials, a glycidyl ether of bisphenol A-type (or AD-type, S-type, F-type), a glycidyl ether of hydrogenated bisphenol A-type, a glycidyl ether of ethyleneoxide adduct bisphenol A-type or F-type, a glycidyl ether of propyleneoxide adduct bisphenol A-type or F-type, a glycidyl ether of phenol novolak resin, a glycidyl ether of cresol novolak resin, a glycidyl ether of bisphenol A novolak resin, a glycidyl ether of naphthalene resin, a glycidyl ether of 3 functional type (or 4 functional type), a glycidyl ether of dicyclopentadiene phenol resin, a glycidyl ester of dimer acid, a glycidyl amine of 3 functional type (or 4 functional type), a glycidyl amine of naphthalene resin and the like.

In particular, in order to improve thermal compression bonding property, low stress and adhesiveness, each of the number of epoxy groups and the number of ethylenically unsaturated groups is preferably three or less; in particular, the number of ethylenically unsaturated groups is preferably two or less. These compounds are not particularly limited, but compounds represented by the following general formulas (13), (14), (15), (16) or (17) are preferably used. In the following general formulas (13) to (17), R¹² and R¹⁶ represent a hydrogen atom or a methyl group, R¹⁰, R¹¹, R¹³ and R¹⁴ represent a divalent organic group and R¹⁵ to R¹⁸ represent an organic group having an epoxy group or an ethylenically unsaturated group.

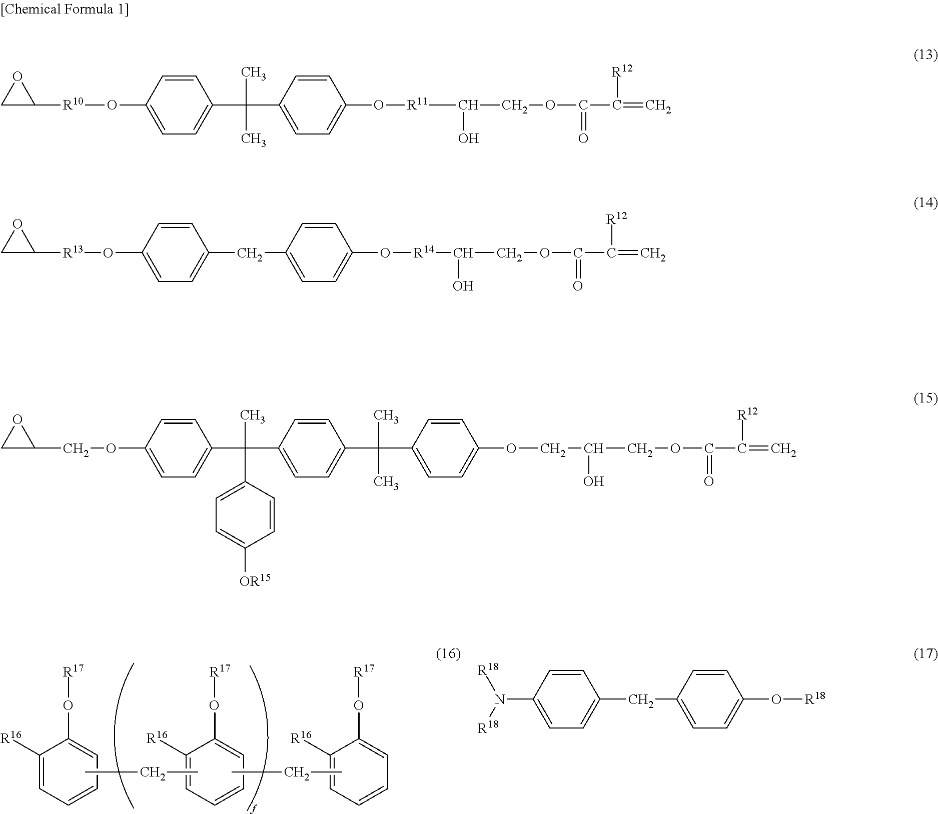

The amount of monofunctional (meth)acrylate described above is preferably 20 to 100 mass %, more preferably 40 to 100 mass % and most preferably 50 to 100 mass %, relative to the total amount of radiation polymerizable compound. When the amount of monofunctional (meth)acrylate falls within the range described above, it is possible to particularly enhance intimate contact with the adherend after being brought to the B-stage and thermal compression bonding property.

The radiation polymerizable compound may contain a two or more functional (meth)acrylate. The two or more functional (meth)acrylate is selected from, for example, diethylene glycol diacrylate, triethylene glycol diacrylate, tetraethylene glycol diacrylate, diethylene glycol dimethacrylate, triethylene glycol dimethacrylate, tetraethylene glycol dimethacrylate, trimethylolpropane diacrylate, trimethylol propane triacrylate, trimethylol propane dimethacrylate, trimethylol propane trimethacrylate, 1,4-butanediol diacrylate, 1,6-hexanediol diacrylate, 1,4-butanediol dimethacrylate, 1,6-hexanediol dimethacrylate, pentaerythritol triacrylate, pentaerythritol tetraacrylate, pentaerythritol trimethacrylate, pentaerythritol tetramethacrylate, dipentaerythritol hexaacrylate, dipentaerythritol hexamethacrylate, styrene, divinylbenzene, 4-vinyltoluene, 4-vinylpyridine, N-vinylpyrrolidone, 2-hydroxyethyl acrylate, 2-hydroxyethyl methacrylate, 1,3-acryloyloxy-2-hydroxyl propane, 1,2-methacryloyloxy-2-hydroxypropane, methylenebisacrylamide, N,N-dimethylacrylamide, N-methylol acrylamide, a triacrylate of tris(β-hydroxyethyl)isocyanurate, a compound expressed by the following general formula (18), a urethane acrylate or urethane methacrylate and an urea acrylate.

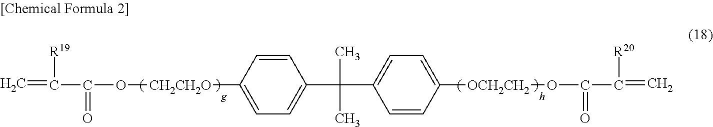

In the formula (18), R¹⁹ and R²⁰ individually represent a hydrogen atom or a methyl group, and g and h individually represent integers of 1 to 20.

These radiation polymerizable compounds can be used alone or in combination of two or more of them. Among them, since the radiation polymerizable compound expressed by the general formula (18) and having a glycol skeleton is preferable, since it can sufficiently provide solvent resistance after curing, and have a low viscosity and a high 5% weight reduction temperature.

Through the use of the radiation polymerizable compound having a high functional group equivalent weight, it is possible to reduce stress and warpage. The radiation polymerizable compound having a high functional group equivalent weight has a functional group equivalent weight of preferably 200 eq/g or more, more preferably 300 eq/g and most preferably 400 eq/g or more. By using the radiation polymerizable compound having a functional group equivalent weight of 200 eq/g or more and having an ether skeleton, a urethane group and/or an isocyanurate group, it is possible to enhance the adhesion of the adhesive composition and reduce stress and warpage. The radiation polymerizable compound having a functional group equivalent weight of 200 eq/g or more and the radiation polymerizable compound having a functional group equivalent weight of 200 eq/g or less may be used together.

The content of the radiation polymerizable compound is preferably 10 to 95 mass %, more preferably 20 to 90 mass % and most preferably 40 to 90 mass % relative to the total amount of adhesive composition. When the content of the radiation polymerization compound is more than 10 mass %, the tack force after being brought to the B-stage tends to be increased; when the content of the radiation polymerization compound is more than 95 mass %, the adhesion strength after the curing tends to be decreased.

The radiation polymerizable compound is preferably liquid at room temperature. The viscosity of the radiation polymerizable compound is preferably 5000 mPa·s or less, more preferably 3000 mPa·s or less, further preferably 2000 mPa·s or less, and most preferably 1000 mPa·s or less. When the viscosity of the radiation polymerizable compound is 5000 mPa·s or more, the viscosity of the adhesive composition tends to increase to make it difficult to prepare the adhesive composition, and to make it difficult to reduce the thickness of the film and make it difficult to perform discharge from the nozzle.

The 5% weight reduction temperature of the radiation polymerizable compound is preferably 120° C. or more, more preferably 150° C. or more and further preferably 180° C. or more. Here, the 5% weight reduction temperature of the radiation polymerizable compound is measured using the thermogravimetry differential thermal measurement device (manufactured by SII NanoTechnology Inc.: TG/DTA6300), at a temperature rise rate of 10° C./minute, under flow of nitrogen (400 ml/min). By using the radiation polymerizable compound whose 5% weight reduction temperature is high, it is possible to reduce the volatilization of the unreacted radiation polymerization compound at the time of the thermal compression bonding or the thermal curing.

The adhesive composition preferably contains a thermosetting resin. As long as the thermosetting resin is a component formed with a reactive compound that causes a cross-linking reaction by heat, it is not particularly limited. The thermosetting resin is selected from, for example, an epoxy resin, a cyanate ester resin, a maleimide resin, an arylnadiimide resin, a phenol resin, a urea resin, a melamine resin, an alkyd resin, an acrylic resin, an unsaturated polyester resin, a diallyl phthalate resin, a silicone resin, a resorcinol-formaldehyde resin, an xylene resin, a furan resin, a polyurethane resin, a ketone resin, a triallyl cyanurate resin, a polyisocyanate resin, a resin containing a tris (2-hydroxyethyl)isocyanurate, a resin containing a triallyl trimellitate, a thermosetting resin synthesized from a cyclopentadiene and a thermosetting resin obtained by trimerizing a dicyanamide. Among them, since it is possible to have excellent adhesion strength at a high temperature, an epoxy resin, a maleimide resin and an arylnadiimide resin are preferable in the combination with a polyimide resin. The thermosetting resins can be used alone or in combination of two or more of them.

As the epoxy resin, a compound with two or more epoxy groups is preferable. In terms of thermal compression bonding property, curing property and the properties of a cured material, a phenol glycidyl ether type epoxy resin is preferable. Examples of this type of epoxy resin include, for example: a glycidyl ether of bisphenol A-type (or AD-type, S-type, F-type), a glycidyl ether of hydrogenated bisphenol A-type, a glycidyl ether of ethylene oxide adduct bisphenol A-type, a glycidyl ether of propylene oxide adduct bisphenol A-type, a glycidyl ether of phenol novolak resin, a glycidyl ether of cresol novolak resin, a glycidyl ether of bisphenol A novolak resin, a glycidyl ether of naphthalene resin, a glycidyl ether of 3 functional type (or 4 functional type), a glycidyl ether of dicyclopentadiene phenol resin, a glycidyl esthr of dimer acid, a glycidyl amine of 3 functional type (or 4 functional type) and a glycidyl amine of naphthalene resin. These can be used alone or in combination of two or more of them.

Preferably, in order to reduce the electromigration and the corrosion of a metal conductor circuit, the epoxy resin is highly pure in which alkali metal ions, alkaline earth metal ions and halogen ions that are impurity ions, especially chlorine ions, hydrolyzable chlorine and the like are reduced to 300 ppm.

The content of the epoxy resin is preferably 1 to 100 mass parts, and more preferably 2 to 50 mass parts relative to 100 mass parts of the radiation polymerizable compound. When the content exceeds 100 mass parts, the tack after the exposure tends to be increased. In contrast, when the content is less than 2 mass parts, it tends to become difficult to obtain sufficient thermal compression bonding property and high-temperature adhesiveness.

The thermosetting resin is preferably liquid at room temperature. The viscosity of the thermosetting resin is preferably 10000 mPa·s or less, more preferably 5000 mPa·s or less, further preferably 3000 mPa·s or less and most preferably 2000 mPa·s or less. When the viscosity is 10000 mPa·s or more, the viscosity of the adhesive composition tends to be increased to make it difficult to reduce the thickness of the film.

The 5% weight reduction temperature of the thermosetting resin is preferably 150° C. or more, more preferably 180° C. or more and further preferably 200° C. or more. Here, the 5% weight reduction temperature of the thermosetting resin is measured using the thermogravimetry differential thermal measurement device (manufactured by SII NanoTechnology Inc.: TG/DTA6300), at a temperature rise rate of 10° C./minute, under flow of nitrogen (400 ml/min). By using the thermosetting compound whose 5% weight reduction temperature is high, it is possible to reduce the volatilization at the time of the thermal compression bonding or the thermal curing. As the thermosetting resin that has such heat resistance, there is an epoxy resin that has an aromatic group. In terms of adhesiveness and heat resistance, in particular, a glycidyl amine of 3 functional type (or 4 functional type), a glycidyl ether of bisphenol A-type (or AD-type, S-type, F-type) is preferably used.

When the epoxy resin is used, the adhesive composition preferably contains a curing accelerator. As long as the curing accelerator is a compound that facilitates the curing/polymerization of the epoxy resin by heating, it is not particularly limited. The curing accelerator is selected from, for example, a phenolic compound, an aliphatic amine, an alicyclic amine, an aromatic polyamine, a polyamide, an aliphatic acid anhydride, an alicyclic acid anhydride, an aromatic acid anhydride, a dicyandiamide, an organic acid dihydrazide, a trifluorideboron amine complex, imidazoles, a dicyandiamide derivative, a dicarboxylic acid dihydrazide, triphenylphosphine, tetraphenylphosphonium tetraphenylborate, 2-ethyl-4-methylimidazole-tetraphenylborate, 1,8-diazabicyclo[5,4,0]undecene-7-tetraphenylborate and a tertiary amine. Among them, in terms of solubility and dispersibility when no solvent is contained, imidazoles are preferably used. The content of the curing accelerator is preferably 0.01 to 50 mass parts relative to 100 mass parts of the epoxy resin.

The reaction start temperature of the imidazoles is preferably 50° C. or more, more preferably 80° C. or more and further preferably 100° C. or more. When the reaction start temperature is 50° C. or less, the viscosity of the adhesive composition tends to increase and to make it difficult to control the film thickness, since the storage stability is reduced.

The imidazoles are preferably particles having an average diameter of preferably 10 μm or less, more preferably 8 μm or less and further preferably 5 μm or less. By using the imidazoles having the diameter of the particles described above, it is possible to suppress the change of the viscosity of the adhesive composition and to reduce the settling of the imidazoles. Moreover, when the thin film is formed, projections and recesses in the surface can be reduced to obtain a more uniform film. Furthermore, an outgassing can be reduced probably since the curing in the resin can be uniformly performed at the time of curing. When the imidazole having a low degree of solubility in the epoxy resin is used, it is possible to obtain good storage stability.

As the imidazoles, imidazoles that are soluble in epoxy resin can also be used. Through the use of the imidazoles described above, it is possible to further reduce projections and recesses in the surface when the thin film is formed. The imidazoles described above are not limited, but examples thereof include 2-ethyl-4-methylimidazole, 1-cyanoethyl-2-methylimidazole, 1-cyanoethyl-2-ethyl-4-methylimidazole, 1-cyanoethyl-2-phenylimidazole, 1-benzyl-2-methylimidazole, 1-benzyl-2-phenylimidazole and the like.

The adhesive composition may contain a phenol compound as the curing agent. As the phenol compound, a phenol compound that has at least two or more phenol hydroxyl groups within the molecule is more preferable. Examples of such compound include, for example, a phenol novolak, a cresol novolak, a t-butylphenol novolac, a dicyclopentadiene cresol novolak, a dicyclopentadiene phenol novolac, a xylylene modified phenol novolac, a naphthol-based compound, a tris phenol-based compound, a tetrakis phenol novolac, a bisphenol A novolac, a poly-p-vinylphenol and a phenol aralkyl resin. Among them, a phenol compound having a number average molecular weight of within a range of 400 to 4000 is preferable. Thus, it is possible to reduce an outgassing that contaminates the semiconductor element or device or the like at the time of heating in the assembly of the semiconductor device. The content of phenol compound is preferably 50 to 120 mass parts, and more preferably 70 to 100 mass parts relative to 100 mass parts of the thermosetting resin.

The maleimide resin used as the thermosetting resin is a compound that has two or more maleimide groups. Examples of the maleimide resin include a bismaleimide resin expressed by the following general formula (IV):

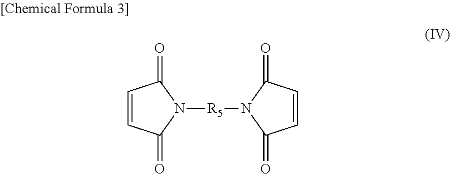

(in the formula, R₅ is a divalent organic group containing an aromatic ring and/or a linear, branched or cyclic aliphatic hydrocarbon group) and a novolak maleimide resin expressed by the following general formula (V):

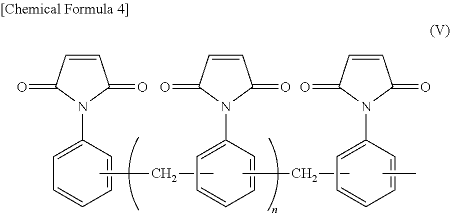

(in the formula, n represents an integer of 0 to 20)
In the formula (IV), R₅ is preferably a benzene residue, a toluene residue, a xylene residue, a naphthalene residue, a linear, branched or cyclic alkyl group or a mixed group thereof. More preferably, R₅ is a divalent organic group expressed by the following chemical formulas. In each of the formulas, n represents an integer of 1 to 10.

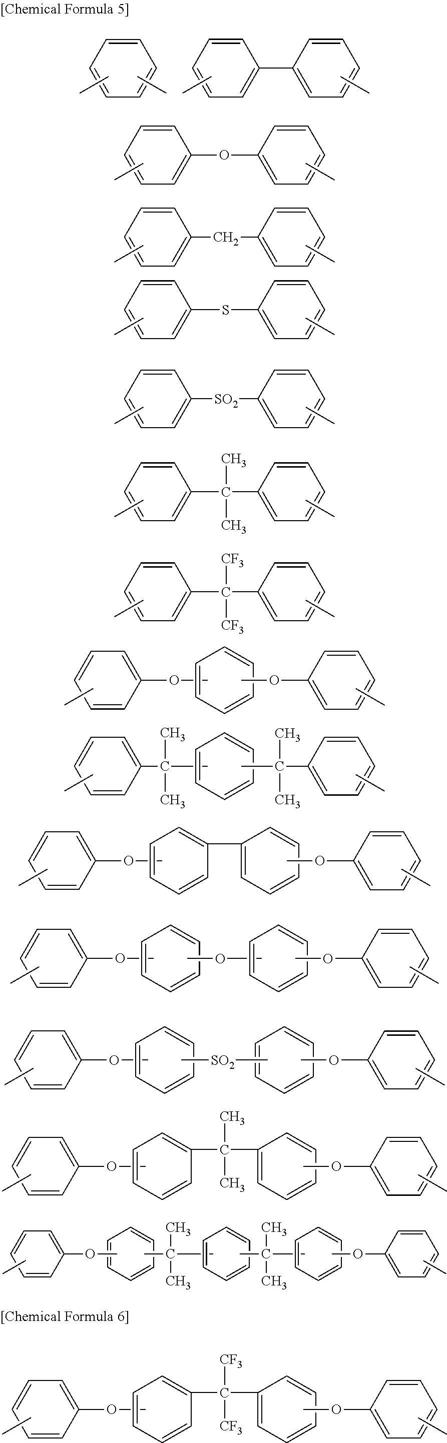

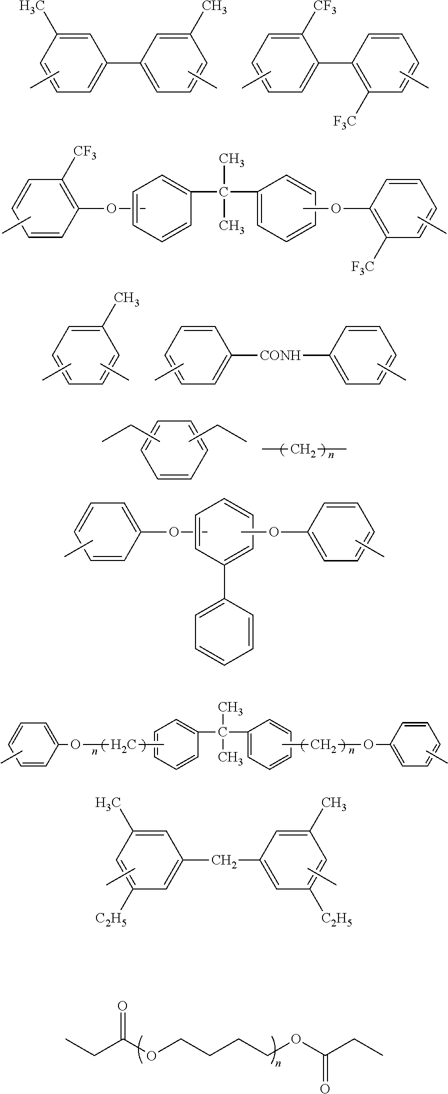

Among them, from the viewpoint of being capable of imparting heat resistance and high-temperature adhesiveness after curing, to the adhesion film, a bismaleimide resin having the following structure:

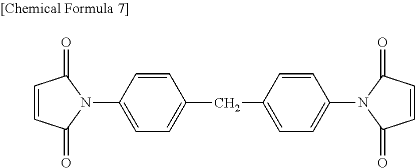

and/or a novolac-type maleimide resin having the following structure:

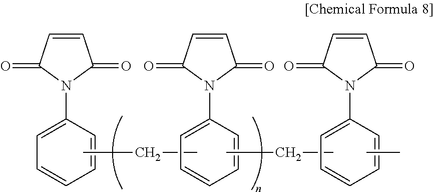

are preferably used. In the formulas, n represents an integer of 1 to 20.

In order to cure the maleimide resin above, an allyl bisphenol A, a cyanate ester compound may be combined with the maleimide resin. A catalyst such as a peroxide can be contained in the adhesive composition. The amount of compound added and the amount of catalyst added and whether or not they are added are adjusted as appropriate within a range in which the intended properties can be ensured.

The allylnadimide resin is a compound having two or more allylnadimide groups. As an example of the allylnadimide resin, there is a bisallylnadimide resin expressed by the following general formula (I).

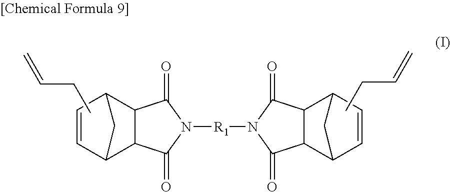

In the formula (I), R₁ represents a divalent organic group containing an aromatic ring and/or a linear, branched or cyclic aliphatic hydrocarbon group. R₁ is preferably a benzene residue, a toluene residue, a xylene residue, a naphthalene residue, a linear, branched or cyclic alkyl group or a mixed group thereof. More preferably, R₁ is a divalent organic group expressed by the following chemical formulas. In each of the formulas, n represents an integer of 1 to 10.

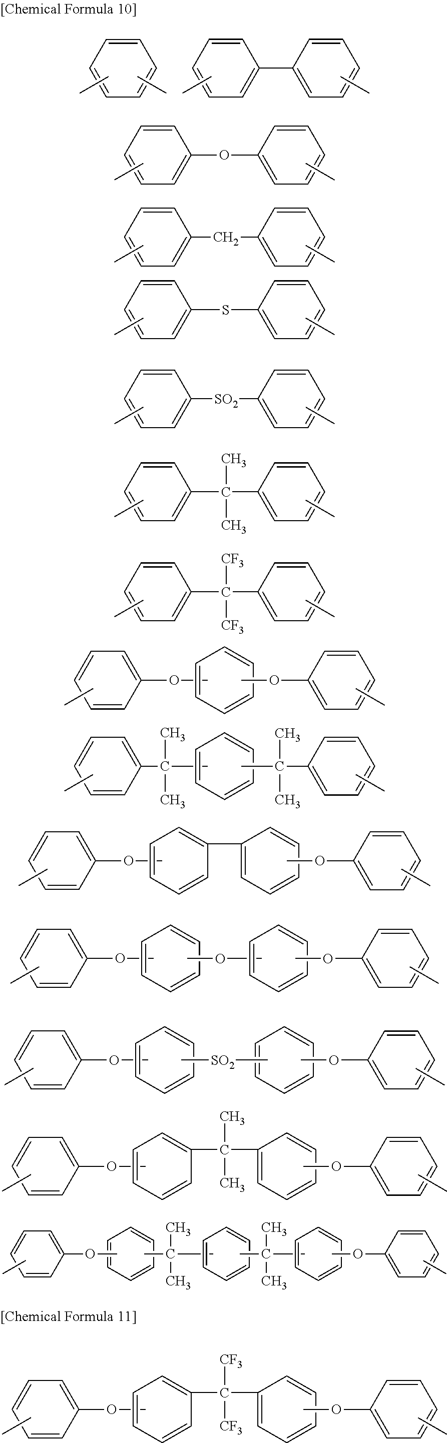

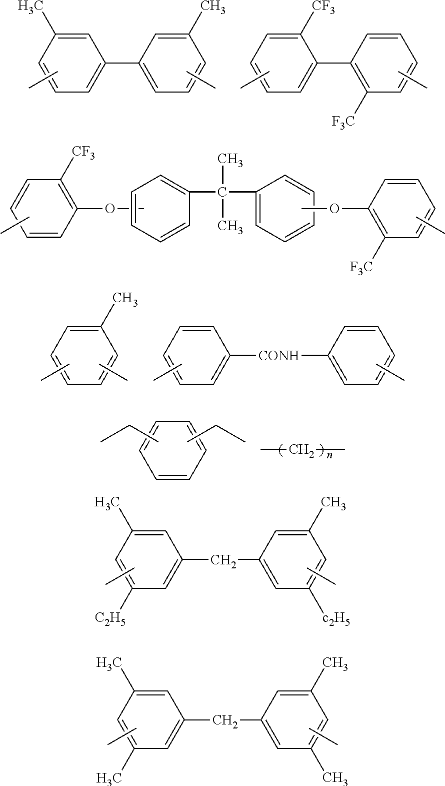

Among them, a liquid hexamethylene type bisallylnadimide expressed by the following chemical formula (II) and a solid xylylene type bisallylnadimide expressed by the following chemical formula (III) and having a low melting point (melting point: 40° C.) are preferable from the viewpoint that these can act also as a compatibilizing agent between different components constituting the adhesive composition and can impart good heat fluidity at the B-stage of the adhesion film. Furthermore, the solid xylylene type bisallylnadimide is more preferable, in addition to good heat fluidity, from the viewpoint of being capable of suppressing the increase in the stickiness of the surface of the film at room temperature, handling, easy peeling-off from a dicing tape at the time of pickup, and the suppression of re-fusion of a cutting surface after dicing.

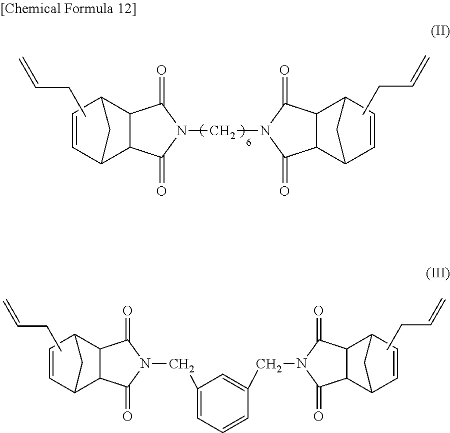

These bisallylnadimides can be used alone or in combination of two or more of them.

The allylnadimide resin requires a curing temperature of 250° C. or more, when cured solely without any catalyst. Furthermore, when a catalyst is used, only a metal corrosive catalyst such as a strong acid or onium salt which can be a serious fault in an electronic material is used, and a temperature of about 250° C. at final curing is required. In combined use of the allylnadimide resin above and any one of a two or more functional acrylate compound or methacrylate compound and a maleimide resin, it is possible to perform curing at a low temperature 200° C. or less (document: A. Renner, A. Kramer, “Allylnadic-imides; A New Class of Heat-Resistant Thermosets”, J. Polym. Sci., Part A Polym. Chem., 27, 1301 (1989).

The adhesive composition may further contain a thermoplastic resin. Through the use of the thermoplastic resin, it is possible to further enhance low stress, intimate contact with the adherend and thermal compression bonding property. The glass transition temperature (Tg) of the thermoplastic resin is preferably 150° C. or less, more preferably 120° C. or less, further more preferably 100° C. or less and most preferably 80° C. or less. When the Tg exceeds 150° C., the viscosity of the adhesive composition tends to increase. Moreover, it tends to be necessary to use a high temperature of 150° C. or more when the adhesive composition is thermal compression bonded to the adherend, and the semiconductor wafer tends to become easily warped.

Here, “Tg” means a main dispersion peak temperature of the thermoplastic resin formed into a film. Through the use of a viscoelasticity analyzer “RSA-2” (trade name) manufactured by Rheometric Ltd., the dynamic viscoelasticity of the film was measured under the conditions of a film thickness of 100 μm, a temperature rise rate of 5° C./minute, a frequency of 1 Hz and a measurement temperature of 0-150 to 300° C., and the main dispersion peak temperature of tan δ was set to Tg.

The weight average molecular weight of the thermoplastic resin is preferably within a range of 5000 to 500000, and more preferably within a range of 10000 to 300000 in that both thermal compression bonding property and high-temperature adhesiveness can be highly achieved at the same time. Here, the “weight average molecular weight” means a weight average molecular weight that is measured in terms of standard polystyrene through the use of a high-performance liquid chromatography “C-R4A” (trade name) manufactured by Shimadzu Corporation.

Examples of the thermoplastic resin include a polyester resin, a polyether resin, a polyimide resin, a polyamide resin, a polyamideimide resin, a polyether imide resin, a polyurethane resin, a polyurethane imide resin, a polyurethane amide imide resin, a siloxane polyimide resin, a polyester imide resin, copolymers thereof, precursors thereof (such as polyamide acid), a polybenzoxazole resin, a phenoxy resin, a polysulfone resin, a polyether sulfone resin, a polyphenylene sulfide resin, a polyester resin, a polyether resin, a polycarbonate resin, a polyether ketone resin, a (meth)acrylate copolymer having a weight average molecular weight of 10000 to 1000000, a novolac resin, a phenol resin and the like. These can be used alone or in combination of two or more of them. Furthermore, a glycol group such as an ethylene glycol or a propylene glycol, a carboxyl group and/or a hydroxyl group may be imparted to the main chain and/or the side chain of these resins.

Among them, the thermoplastic resin is preferably a resin having an imide group from the viewpoint of high-temperature adhesiveness and heat resistance. As the resin having an imide group, there is used at least one kind of resin selected, for example, from a group consisting of a polyimide resin, a polyamide imide resin, a polyether imide resin, a polyurethane imide resin, a polyurethane amide imide resin, a siloxane polyimide resin and a polyester imide resin.

For example, the polyimide resin can be synthesized by the following method. The resin can be obtained by performing a condensation reaction of tetracarboxylic acid dianhydride and a diamine by a known method. That is, in an organic solvent, either in equal moles of the tetracarboxylic acid dianhydride and the diamine or by adjusting, as necessary, the composition ratio such that a total of amine is preferably 0.5 to 2.0 moles and more preferably 0.8 to 1.0 mole relative to total 1.0 mole of the tetracarboxylic acid dianhydride, an addition reaction is performed at a reaction temperature of 80° C. or less and preferably at a temperature of 0 to 60° C. As the reaction proceeds, the viscosity of the reaction solution is gradually increased, and thus a polyamide acid that is a precursor of a polyimide resin is produced. Meanwhile, in order to suppress the decrease in the properties of the resin composition, the tetracarboxylic acid dianhydride described above is preferably subjected to recrystallization refining processing by using acetic acid anhydride.

With respect to the composition ratio of the tetracarboxylic acid dianhydride and the diamine in the condensation reaction, when a total of the diamine exceeds 2.0 moles relative to a total 1.0 mole of the tetracarboxylic acid dianhydride, the amount of polyimide oligomer at the amine end in the obtained polyimide resin tends to be increased, and the weight average molecular weight of the polyimide resin is reduced, with the result that various properties of the resin composition including heat resistance tends to become insufficient. In contrast, when the total of the diamine is less than 0.5 mole relative to a total 1.0 mole of the tetracarboxylic acid dianhydride, the amount of polyimide resin oligomer of acid ends tends to be increased, and the weight average molecular weight of the polyimide resin is reduced, with the result that various properties of the resin composition including heat resistance tend to be insufficient.

The polyimide resin can be obtained by performing ring-closing dehydration on the reactant (polyamide acid). The ring-closing dehydration can be performed such as by a heat ring-closure method using heat processing or a chemical ring-closure method using a dehydrating agent.

The tetracarboxylic acid dianhydride used as a raw material of the polyimide resin is not particularly limited, and examples thereof include pyromellitic acid dianhydride, 3,3′,4,4′-biphenyltetracarboxylic acid dianhydride, 2,2′,3,3′-biphenyltetracarboxylic acid dianhydride, 2,2-bis(3,4-dicarboxyphenyl)propane dianhydride, 2,2-bis (2,3-dicarboxyphenyl)propane dianhydride, 1,1-bis(2,3-dicarboxyphenyl)ethane dianhydride, 1,1-bis(3,4-dicarboxyphenyl)ethane dianhydride, bis(2,3-dicarboxyphenyl)methane dianhydride, bis(3,4-dicarboxyphenyl)methane dianhydride, bis(3,4-dicarboxyphenyl)sulfone dianhydride, 3,4,9,10-perylenetetracarboxylic acid dianhydride, bis(3,4-dicarboxyphenyl)ether dianhydride, benzene-1,2,3,4-tetracarboxylic acid dianhydride, 3,4,3′,4′-benzophenone tetracarboxylic acid dianhydride, 2,3,2′,3′-benzophenone tetracarboxylic acid dianhydride, 3,3,3′,4′-benzophenone tetracarboxylic acid dianhydride, 1,2,5,6-naphthalene tetracarboxylic acid dianhydride, 1,4,5,8-naphthalene tetracarboxylic acid dianhydride, 2,3,6,7-naphthalene tetracarboxylic acid dianhydride, 1,2,4,5-naphthalene tetracarboxylic acid dianhydride, 2,6-dichloronaphthalene-1,4,5,8-tetracarboxylic acid dianhydride, 2,7-dichloronaphthalene-1,4,5,8-tetracarboxylic acid dianhydride, 2,3,6,7-tetrachloronaphthalene-1,4,5,8-tetracarboxylic acid dianhydride, phenanthrene-1,8,9,10-tetracarboxylic acid dianhydride, pyrazine-2,3,5,6-tetracarboxylic acid dianhydride, thiophene-2,3,5,6-tetracarboxylic acid dianhydride, 2,3,3′,4′-biphenyltetracarboxylic acid dianhydride, 3,4,3,4′-biphenyltetracarboxylic acid dianhydride, 2,3,2′,3′-biphenyltetracarboxylic acid dianhydride, bis(3,4-dicarboxyphenyl)dimethylsilane dianhydride, bis(3,4-dicarboxyphenyl)methylphenylsilane dianhydride, bis(3,4-dicarboxyphenyl)diphenylsilane dianhydride, 1,4-bis(3,4-dicarboxyphenyldimethylsilyl)benzene dianhydride, 1,3-bis(3,4-dicarboxyphenyl)-1,1,3,3-tetramethyldicyclohexane dianhydride, p-phenylenebis(trimellitate anhydride), ethylenetetracarboxylic acid dianhydride, 1,2,3,4-butanetetracarboxylic acid dianhydride, decahydronaphthalene-1,4,5,8-tetracarboxylic acid dianhydride, 4,8-dimethyl-1,2,3,5,6,7-hexahydronaphthalene-1,2,5,6-tetracarboxylic acid dianhydride, cyclopentane-1,2,3,4-tetracarboxylic acid dianhydride, pyrrolidine-2,3,4,5-tetracarboxylic acid dianhydride, 1,2,3,4-cyclobutane tetracarboxylic acid dianhydride, bis(exo-bicyclo[2,2,1]heptane-2,3-dicarboxylic acid dianhydride, bicyclo-[2,2,2]-oct-7-en-2,3,5,6-tetracarboxylic acid dianhydride, 2,2-bis(3,4-dicarboxyphenyl)propane dianhydride, 2,2-bis[4-(3,4-dicarboxyphenyl)phenyl]propane dianhydride, 2,2-bis(3,4-dicarboxyphenyl)hexafluoropropane dianhydride, 2,2-bis[4-(3,4-dicarboxyphenyl)phenyl]hexafluoropropane dianhydride, 4,4′-bis(3,4-dicarboxyphenoxy)diphenyl sulfide dianhydride, 1,4-bis(2-hydroxyhexafluoroisopropyl)benzene bis(trimellitic anhydride), 1,3-bis(2-hydroxyhexafluoroisopropyl)benzene bis(trimellitic anhydride), 5-(2,5-dioxotetrahydrofuryl)-3-methyl-3-cyclohexene-1,2-dicarboxylic acid dianhydride, tetrahydrofuran-2,3,4,5-tetracarboxylic acid dianhydride, and a tetracarboxylic acid dianhydride expressed by the following general formula (1) and the like. In the general formula (1), a represents an integer of 2 to 20.

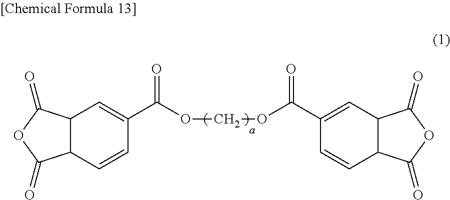

The tetracarboxylic acid dianhydride expressed by the above general formula (1) can be synthesized from, for example, a trimellitic anhydride monochloride and the corresponding diol. Examples thereof include 1,2-(ethylene)bis(trimellitate anhydride), 1,3-(trimethylene) bis(trimellitate anhydride), 1,4-(tetramethylene)bis(trimellitate anhydride), 1,5-(pentamethylene)bis(trimellitate anhydride), 1,6-(hexamethylene)bis(trimellitate anhydride), 1,7-(heptamethylene) bis(trimellitate anhydride), 1,8-(octamethylene)bis(trimellitate anhydride), 1,9-(nonamethylene)bis(trimellitate anhydride), 1,10-(decamethylene)bis(trimellitate anhydride), 1,12-(dodecamethylene)bis(trimellitate anhydride), 1,16-(hexadecamethylene)bis(trimellitate anhydride), 1,18-(octadecamethylene)bis(trimellitate anhydride) and the like.

Furthermore, from the viewpoint of imparting good solubility in a solvent and moisture resistance and transparency to light of 365 nm, to the tetracarboxylic acid dianhydride, a tetracarboxylic acid dianhydride expressed by the following general formula (2) or (3) is preferable.

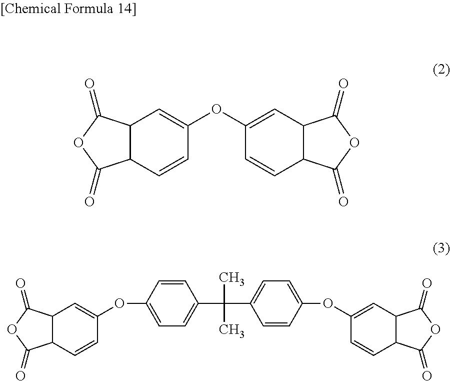

The tetracarboxylic acid dianhydrides described above can be used alone or in combination of two or more of them.

The diamine used as the raw material for the polyimide resin described above is not particularly limited, and examples thereof include, for example, an aromatic diamine such as o-phenylenediamine, m-phenylenediamine, p-phenylenediamine, 3,3′-diaminodiphenyl ether, 3,4′-diaminodiphenyl ether, 4,4′-diaminodiphenyl ether, 3,3′-diaminodiphenylmethane, 3,4′-diaminodiphenylmethane, 4,4′-diaminodiphenyl ether methane, bis(4-amino-3,5-dimethylphenyl)methane, bis(4-amino-3,5-diisopropylphenyl)methane, 3,3-diaminodiphenyldifluoromethane, 3,4-diaminodiphenyldifluoromethane, 4,4′-diaminodiphenyldifluoromethane, 3,3′-diaminodiphenylsulfone, 3,4′-diaminodiphenyl sulfone, 4,4′-diaminodiphenylsulfone, 3,3′-diaminodiphenyl sulfide, 3,4′-diaminodiphenyl sulfide, 4,4′-diaminodiphenyl sulfide, 3,3′-diaminodiphenyl ketone, 3,4′-diaminodiphenyl ketone, 4,4′-diaminodiphenyl ketone, 2,2-bis(3-aminophenyl)propane, 2,2′-(3,4′-diaminodiphenyl)propane, 2,2-bis(4-aminophenyl)propane, 2,2-bis(3-aminophenyl)hexafluoropropane, 2,2-(3,4′-diaminodiphenyl)hexafluoropropane, 2,2-bis(4-aminophenyl)hexafluoropropane, 1,3-bis(3-aminophenoxy)benzene, 1,4-bis(3-aminophenoxy)benzene, 1,4-bis(4-aminophenoxy)benzene, 3,3′-(1,4-phenylenebis(1-methylethylidene))bisaniline, 3,4′-(1,4-phenylenebis(1-methylethylidene))bisaniline, 4,4′-(1,4-phenylenebis(1-methylethylidene))bisaniline, 2,2-bis(4-(3-aminophenoxy)phenyl)propane, 2,2-bis(4-(3-aminophenoxy)phenyl)hexafluoropropane, 2,2-bis(4-(4-aminophenoxy)phenyl)hexafluoropropane, bis(4-(3-aminoenoxy)phenyl) sulfide, bis(4-(4-aminoenoxy)phenyl) sulfide, bis(4-(3-aminoenoxy)phenyl)sulfone, bis(4-(4-aminoenoxy)phenyl)sulfone, 3,3′-dihydroxy-4,4′-diaminobiphenyl, 3,5-diaminobenzoic acid and the like, 1,3-bis(aminomethyl)cyclohexane, 2,2-bis(4-aminophenoxyphenyl)propane, an aliphatic ether diamine expressed by the following general formula (8), a siloxane diamine expressed by the following general formula (9) and the like.

Among the diamines described above, from the viewpoint of imparting compatibility with other components to the diamines, an aliphatic ether diamine expressed by the following general formula (8) is preferable, and ethylene glycol-based and/or propylene glycol-based diamine is more preferable. In the following general formula (8), R¹, R² and R³ individually represent an alkylene group of 1 to 10 carbons and b represents an integer of 2 to 80.

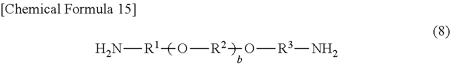

Specific examples of such aliphatic ether diamines include aliphatic diamines including polyoxy alkylene diamines such as Jeffamine D-230, D-400, D-2000, D-4000, ED-600, ED-900, ED-2000 and EDR-148 manufactured by Sun Techono Chemical Co., Ltd., and polyether amines D-230, D-400 and D-2000 manufactured by BASF SE. The amount of these diamines described above is preferably 20 or more mole % and more preferably 50 or more mole % relative to all diamines, from the viewpoint of the fact that compatibility with other components having different compositions, and thermal compression bonding property and high-temperature adhesiveness can be highly achieved at the same time.

As the diamine described above, in order to provide intimate contact and adhesiveness at room temperature, a siloxane diamine expressed by the following general formula (9) is preferable. In the following general formula (9), R⁴ and R⁹ individually represent an alkylene group of 1 to 5 carbons or a phenylene group that may have a substituent, R⁵, R⁶, R⁷ and R⁸ individually represent an alkylene group of 1 to 5 carbons, a phenyl group or a phenoxy group and d represents an integer of 1 to 5.

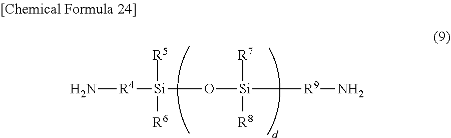

The content of the diamine described above is preferably 0.5 to 80 mole % relative to all diamines, and is further preferably 1 to 50 mole % from the point that a thermal compression bonding property and high-temperature adhesiveness can be highly achieved at the same time. When it is below 0.5 mole %, the effect produced by addition of the siloxane diamine becomes smaller, and when it exceeds 80 mole %, compatibility with other components and high-temperature adhesiveness tend to be decreased.

Specific examples of the siloxane diamines expressed by the following general formula (9) where d represents 1 include: 1,1,3,3-tetramethyl-1,3-bis(4-aminophenyl)disiloxane, 1,1,3,3-tetra phenoxy-1,3-bis(4-aminoethyl)disiloxane, 1,1,3,3-tetraphenyl-1,3-bis(2-aminoethyl)disiloxane, 1,1,3,3-tetraphenyl-1,3-bis(3-aminopropyl)disiloxane, 1,1,3,3-tetramethyl-1,3-bis(2-aminoethyl)disiloxane, 1,1,3,3-tetramethyl-1,3-bis(3-aminopropyl)disiloxane, 1,1,3,3-tetramethyl-1,3-bis(3-aminobutyl)disiloxane, 1,3-dimethyl-1,3-dimethoxy-1,3-bis(4-aminobutyl)disiloxane and the like, where d represents 2 include: 1,1,3,3,5,5-hexamethyl-1,5-bis(4-aminophenyl)trisiloxane, 1,1,5,5-tetraphenyl-3,3-dimethyl-1,5-bis(3-aminopropyl)trisiloxane, 1,1,5,5-tetraphenyl-3,3-dimethoxy-1,5-bis(4-aminobutyl)trisiloxane, 1,1,5,5-tetraphenyl-3,3-dimethoxy-1,5-bis(5-aminopentyl)trisiloxane, 1,1,5,5-tetramethyl-3,3-dimethoxy-1,5-bis(2-aminoethyl)trisiloxane, 1,1,5,5-tetramethyl-3,3-dimethoxy-1,5-bis(4-aminobutyl)trisiloxane, 1,1,5,5-tetramethyl-3,3-dimethoxy-1,5-bis(5-aminopentyl)trisiloxane, 1,1,3,3,5,5-hexamethyl-1,5-bis(3-aminopropyl)trisiloxane, 1,1,3,3,5,5-hexaethyl-1,5-bis(3-aminopropyl)tri siloxane, 1,1,3,3,5,5-hexapropyl-1,5-bis(3-aminopropyl)trisiloxane and the like.

The diamines described above can used alone or in combination of two or more of them.

The polyimide resins above can be used alone or by mixing two or more of them as necessary.

When the composition of the polyimide resin is determined, it is preferably designed such that Tg thereof is 150° C. or less. As the diamine that is a raw material of the polyimide resin, an aliphatic ether diamine expressed by the general formula (8) is particularly preferably used.

When the polyimide resin described above is synthesized, by putting a monofunctional acid anhydride and/or a monofunctional amine such as a compound expressed by the following formula (10), (11) or (12) into a condensation reaction solution, it is possible to introduce, into polymer ends, a functional group other than an acid anhydride or a diamine. Thus, it is also possible to reduce the molecular weight of the polymer and the viscosity of the adhesive resin composition and enhance the thermal compression bonding property.

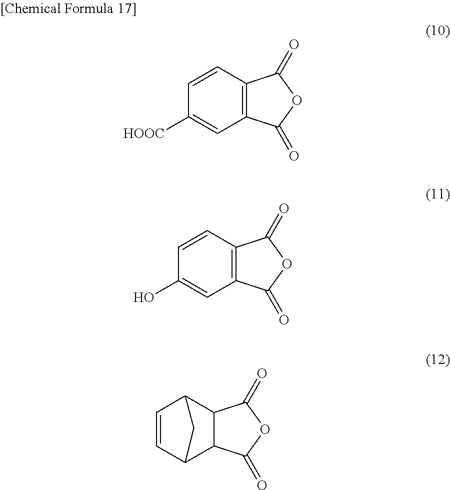

The thermosetting resin may have, in the main chain and/or the side chain thereof, a functional group such as an imidazole group having the function of facilitating the curing of epoxy resin. For example, a polyimide resin having an imidazole group can be obtained, for example, by a method using a diamine containing an imidazole group expressed by the following chemical formula as a part of a diamine used for synthesizing the polyimide resin.

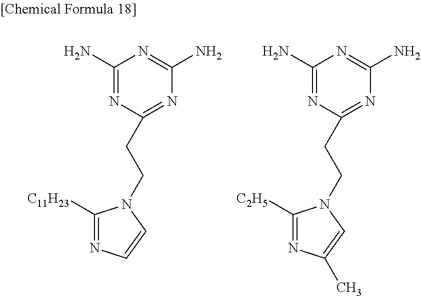

Since the uniform B-stage can be achieved, the transmittance of the polyimide resin above when it is formed into a film with a thickness of 30 μm with respect to 365 nm is preferably 10% or more, and since the B-stage with a low exposure amount can be achieved, it is further preferably 20% or more. Such polyimide resin can be synthesized by reacting, for example, the acid anhydride expressed by the general formula (2) described above with the aliphatic ether diamine expressed by the general formula (8) described above and/or the siloxane diamine expressed by the general formula (9) described above.

As the thermoplastic resin described above, from the point of suppressing the increase in viscosity and further reducing an undissolved residue in the adhesive composition, a thermoplastic resin that is liquid at room temperature (25° C.) is preferably used. By using such thermoplastic resin, the reaction can be performed by heating without use of solvent, and it is useful when the adhesive composition containing substantially no solvent, in terms of the decrease in the step of removal of the solvent, the reduction in the solvent left and the decrease in the precipitation step. The liquid thermoplastic resin can easily be removed from the reaction furnace. The liquid thermoplastic resin described above is not particularly limited. Examples of the liquid thermoplastic resin include: rubber polymers such as polybutadiene, an acrylonitrile butadiene oligomer, polyisoprene and polybutene, polyolefin, an acrylic polymer, a silicone polymer, polyurethane, a polyimide, a polyamide imide and the like. Among them, a polyimide resin is preferably used.

The liquid polyimide resin can be obtained, for example, by reacting the acid anhydride described above with an aliphatic ether diamine or a siloxane diamine. In the method of synthesizing the liquid polyimide resin, it can be obtained by dispersing, without addition of solvent, the acid anhydride in an aliphatic ether diamine or a siloxane diamine and heating them.

The adhesive composition of the present embodiment may contain a sensitizer as necessary. Examples of the sensitizer include, for example, camphorquinone, benzyl, diacetyl, benzyldimethyl ketal, benzyldiethyl ketal, benzyldi(2-methoxyethyl) ketal, 4,4′-dimethylbenzyl-dimethyl ketal, anthraquinone, 1-chloroanthraquinone, 2-chloroanthraquinone, 1,2-benzanthraquinone, 1-hydroxyanthraquinone, 1-methylanthraquinone, 2-ethylanthraquinone, 1-bromoanthraquinone, thioxanthone, 2-isopropylthioxanthone, 2-nitrothioxanthone, 2-methylthioxanthone, 2,4-dimethylthioxanthone, 2,4-diethylthioxanthone, 2,4-diisopropylthioxanthone, 2-chloro-7-trifluoromethylthioxanthone, thioxanthone-10,10-dioxide, thioxanthone-10-oxide, a benzoin methyl ether, a benzoin ethyl ether, an isopropyl ether, a benzoin isobutyl ether, benzophenone, bis(4-dimethylaminophenyl)ketone, 4,4-bisdiethylaminobenzophenone and a compound containing an azido group. They can be used alone or in combination of two or more of them.

The adhesive composition of the present embodiment can contain a thermal radical generator as necessary. The thermal radical generator is preferably an organic peroxide. The one minute half-life temperature of the organic peroxide is preferably 80° C. or more, more preferably 100° C. or more and most preferably 120° C. or more. The organic peroxide is selected in consideration of the preparing conditions of the adhesive composition, the film formation temperature, the curing (sticking) conditions, other process conditions, the storage stability and the like. The peroxide that can be used is not particularly limited. Examples thereof include, for example, 2,5-dimethyl-2,5-di(t-butylperoxyhexane), dicumylperoxide, t-butylperoxy-2-ethylhexanoate, t-hexylperoxy-2-ethylhexanoate, 1,1-bis(t-butylperoxy)-3,3,5-trimethylcyclohexane, 1,1-bis(t-hexylperoxy)-3,3,5-trimethylcyclohexane, bis (4-t-butylcyclohexyl)peroxydicarbonate and the like. These can be used alone or by mixing two or more of them. When the organic peroxide is contained, it is possible to make react the radiation polymerizable compound that is left and does not react after exposure to reduce outgassing and to enhance the adhesion.

The amount of thermal radical generator added is preferably 0.01 to 20 mass %, further preferably 0.1 to 10 mass % and most preferably 0.5 to 5 mass %, relative to the total amount of the radiation polymerizable compound. When it is less than 0.01 mass %, the curing property is decreased, and thus the effects of the addition tend to be reduced; when it exceeds 5 mass %, the amount of outgassing tends to be increased, or the storage stability tends to be decreased.

The thermal radical generator is preferably a compound having a half-life temperature of 80° C. or more. Examples thereof include Perhexa 25B (manufactured by NOF Corporation), 2,5-dimethyl-2,5-di(t-butylperoxyhexane) (one minute half-life temperature: 180° C.), Percumyll D (manufactured by NOF Corporation) and dicumyl peroxide (one minute half-life temperature: 175° C.).

In order to provide storage stability, process adaptability or oxidation prevention, a polymerization inhibitor or an antioxidant such as quinones, polyhydric phenols, phenols, phosphites and sulfurs may be further added to the adhesive composition of the present embodiment as long as the curing property is not degraded.

A filler can be contained in the adhesive composition as necessary. Examples of the filler include, for example: metal fillers such as silver powder, gold powder, copper powder, nickel powder and tin; inorganic fillers such as alumina, aluminum hydroxide, magnesium hydroxide, calcium carbonate, magnesium carbonate, calcium silicate, magnesium silicate, calcium oxide, magnesium oxide, aluminum oxide, aluminum nitride, crystalline silica, amorphous silica, boron nitride, titania, glass, iron oxide, and ceramic; and organic fillers such as carbon and rubber fillers. The use of them is not particularly limited regardless of their types, shapes or the like.

The fillers above can be selected and used according to the desired functions. For example, the metal fillers are added in order to impart electrical conductivity, thermal conductivity, thixotropy and the like to the resin composition, the nonmetal inorganic fillers are added in order to impart thermal conductivity, pickup property (easy peeling-off from a dicing tape), low-heat expandability, low moisture absorption and the like to the adhesive layer, and the organic fillers are added in order to impart toughness and the like to the adhesive layer.

The metal fillers, the inorganic fillers and the organic fillers can be used alone or in combination of two or more of them. Among them, since electrical conductivity, thermal conductivity, low moisture absorption, insulation and the like that are required for the adhesive material of a semiconductor device can be provided, the metal fillers, the inorganic fillers or the insulating fillers are preferable. Among the organic fillers or the insulating fillers, since the dispersion over resin varnish is good and high adhesion can be provided when heated, the silica filler is more preferable.

In the fillers described above, it is preferable that the average particle diameter is 10 μm or less and the maximum particle diameter is 30 μm or less, and it is more preferable that the average particle diameter is 5 μm or less and the maximum particle diameter is 20 μm or less. When the average particle diameter exceeds 10 μm and the maximum particle diameter exceeds 30 μm, the effect of enhancing the destructive toughness tends to be not sufficiently obtained. The lower limits of the average particle diameter and the maximum particle diameter are not particularly limited, but in general, each of them is 0.001 μM.

The amount of the filler contained is determined depending on the properties or functions imparted, and it is preferably 0 to 50 mass %, more preferably 1 to 40 mass % and further preferably 3 to 30 mass %, relative to the total amount of resin component and filler. By the increase in the amount of filler, it is possible to lower the alpha, reduce the moisture absorption and increase the coefficient of elasticity, with the result that it is possible to effectively enhance dicing property (cutting property with a dicer blade), wire bonding property (ultrasonic efficiency) and adhesion strength when heated.

If the amount of the filler is increased more than necessary, the viscosity tends to be increased and the thermal compression bonding property tends to be degraded. Therefore, the amount of the filler contained preferably falls within the range described above. The optimum filler content is determined such that the required properties are balanced. Mixing and kneading when using the fillers can be performed by combining, as necessary, dispersing machines such as an agitator, a milling machine, a three-shaft roll and a ball mill that are normally used.

Various coupling agents can be added to the adhesive composition in order to enhance interface coupling between different materials. Examples of the coupling agent include, for example, silane, titanium, aluminum-based coupling agents; among them, since it is effective, the silane-based coupling agent is preferable, and a compound having a thermosetting functional group such as an epoxy group or a radiation polymerizable functional group such as methacrylate and/or acrylate is more preferable. The boiling point and/or decomposition temperature of the silane-based coupling agent above is preferably 150° C. or more, more preferably 180° C. or more and further preferably 200° C. or more. In other words, the silane-based coupling agent having a boiling point and/or decomposition temperature of 200° C. or more and having a thermosetting functional group such as an epoxy group or a radiation polymerizable functional group such as methacrylate and/or acrylate is most preferably used. The amount of coupling agent above is preferably 0.01 to 20 mass parts relative to 100 mass parts of the adhesive composition used in terms of its effects, the heat resistance and the cost.

In order to adsorb ion impurities and enhance the reliability of insulation when moisture is absorbed, an ion capturing agent can be further added to the adhesive composition of the present embodiment. Such ion capturing agent is not particularly limited but it includes, for example, a triazine thiol compound, a compound such as a phenolic reducing agent that is known as a copper damage prevention agent for preventing copper from being ionized and dissolved, and powdered bismuth, antimony, magnesium, aluminum, zirconium, calcium, titanium, tin-based inorganic compounds and their mixtures. Specific examples, which are not particularly limited, include inorganic ion capturing agents manufactured by Toagosei Co., Ltd. such as IXE-300 (antimony-based), IXE-500 (bismuth-based), IXE-600 (antimony, bismuth-based mixture), IXE-700 (magnesium, aluminum-based mixture), IXE-800 (zirconium-based) and IXE-1100 (calcium-based). These can be used alone or by mixing two or more of them. The amount of the ion capturing agent above and used is preferably 0.01 to 10 mass parts relative to 100 mass parts of the adhesive composition in terms of the effects of the addition, the heat resistance, the cost and the like.

### Example

The present invention will be further specifically described below using examples. However, the present invention is not limited to the following examples.

<Thermoplastic Resin (Polyimide Resin)>.

(PI-1)

In a flask provided with a stirrer, a thermometer, and a nitrogen substitution device, 5.72 g (0.02 mol) of 5,5′-methylenebis(anthranilic acid) (MBAA), 13.57 g (0.03 mol) of aliphatic ether diamine (trade name “D-400”), 2.48 g (0.01 mol) of 1,1,3,3-tetramethyl-1,3-bis(3-aminopropyl) disiloxane (trade name “BY16-871EG”, manufactured by Dow Corning Toray Co., Ltd.), 8.17 g (0.04 mol) of 1,4-butanediol bis(3-aminopropyl)ether (trade name “B-12”, manufactured by Tokyo Chemical Industry Co., Ltd., molecular weight of 204.31), and 110 g of NMP as a solvent were loaded, and then these diamines were dissolved in the solvent by stirring.

While cooling the above-described flask in an ice bath, 29.35 g (0.09 mol) of 4,4′-oxydiphthalic dianhydride (ODPA) and 3.84 g (0.02 mol) of trimellitic anhydride (TAA) were added in small amounts to the solution in the flask. After finishing the addition, stirring was performed at room temperature for 5 hours. Thereafter, a reflux condenser with a water receptor was attached to the flask, 70.5 g of xylene was added, the temperature of the solution was increased to 180° C. while blowing a nitrogen gas, which was kept for 5 hours, azeotropic removal of xylene was performed along with water, and the varnish of a polyimide resin PI-1 was obtained. When GPC measurement of the polyimide resin PI-1 was performed, the weight average molecular weight (Mw) was 21000 in terms of standard polystyrene. In addition, the Tg of the polyimide resin PI-1 was 55° C.

The varnish of the obtained polyimide resin PI-1 was used to be subjected to reprecipitation purification with pure water three times, which was then heat-dried at 60° C. for 3 days through the use of a vacuum oven, and thus the solid of the polyimide resin PI-1 was obtained.

(PI-2)

In a 500 mL flask provided with a stirrer, a thermometer, and a nitrogen substitution device (nitrogen inflow tube), 140 g (0.07 mol) of polyoxypropylenediamine (trade name “D-2000”, molecular weight: about 2000, manufactured by BASF) and 3.72 g (0.015 mol) of 1,1,3,3-tetramethyl-1,3-bis(3-aminopropyl)disiloxane (trade name “BY16-871EG”, manufactured by Dow Corning Toray Co., Ltd.), and 31.0 g (0.1 mol) of ODPA were gradually added to the solution in the flask. After finishing the addition, it was stirred at room temperature for 5 hours. Thereafter, the reflux condenser with the water receiver was attached to the flask and the temperature of the solution was increased to 180° C. while nitrogen gas was being blown therein, its temperature was maintained for five hours and the water was removed, with the result that the liquid polyimide resin PI-2 was obtained. When GPC measurement of the polyimide resin PI-2 was performed, it had a weight average molecular weight (Mw) of 40000 in terms of standard polystyrene. In addition, the Tg of the polyimide resin PI-2 was 20° C. or less.

(PI-3)

In a 500 mL flask provided with a stirrer, a thermometer, and a nitrogen substitution device (nitrogen inflow tube), 100 g (0.05 mol) of polyoxypropylenediamine (trade name “D-2000”, molecular weight: about 2000, manufactured by BASF) and 3.72 g (0.015 mol) of 1,1,3,3-tetramethyl-1,3-bis(3-aminopropyl)disiloxane (trade name “BY16-871EG”, manufactured by Dow Corning Toray Co., Ltd.), and 7.18 g (0.02 mol) of 2,4-diamino-6-[2′-undecylimidazolyl(1′)]ethyl-s-triazine (trade name “C11Z-A”, manufactured by Shikoku Chemicals Corporation), and 31.0 g (0.1 mol) of ODPA were added in small amounts to a solution in the flask. After finishing the addition, it was stirred at room temperature for 5 hours. Thereafter, the reflux condenser with the water receiver was attached to the flask, and the temperature of the solution was increased to 180° C. while nitrogen gas was being blown therein its temperature was maintained for five hours and the water was removed, with the result that the liquid polyimide resin PI-3 was obtained. When GPC measurement of the polyimide resin PI-3 was performed, it had a weight average molecular weight (Mw) of 40000 in terms of standard polystyrene. In addition, the Tg of the polyimide resin PI-3 was 20° C. or less.

Preparation of Adhesive Compositions

Through the use of the polyimide resins PI-1, PI-2, and PI-3 obtained as described above, respective constituents were blended at composition ratios (unit: part(s) by mass) listed in Table 1 described below and the adhesive compositions of Examples 1-8 and Comparative Examples 1-6 were obtained.

In Table 1, each of symbols means the followings.

### (Thermosetting Resins)

YDF-8170C: manufactured by Tohto Kasei Co., Ltd., bisphenol F bisglycidyl ether (5% weight reduction temperature: 270° C., viscosity: 1300 mPa·s)

630LSD: manufactured by Japan Epoxy Resins Co., Ltd., glycidyl amine type epoxy resin (5% weight reduction temperature: 240° C., viscosity: 600 mPa·s)

### (Radiation-Polymerizable Compounds)

A-BPE4: manufactured by Shin Nakamura Chemical Co., Ltd., ethoxylated bisphenol A acrylate (5% weight reduction temperature: 330° C., viscosity: 980 mPa·s),

M-140: manufactured by Toagosei Co., Ltd., 2-(1,2-cyclohexacarboxylmide)ethyl acrylate (5% weight reduction temperature: 200° C., viscosity: 450 mPa·s)

AMP-20GY: manufactured by Shin Nakamura Chemical Co., Ltd., phenoxydiethylene glycol acrylate (5% weight reduction temperature: 175° C., viscosity: 16 mPa·s)

### (Curing Accelerator)

2PZCNS-PW: manufactured by Shikoku Chemicals Corporation, 1-cyanoethyl-2-phenylimidazoliumtrimellitate (5% weight reduction temperature: 220° C., average particle diameter: about 4 μm) (Photoinitiator)

I-651: manufactured by Ciba Japan K.K., 2,2-dimethoxy-1,2-diphenylethane-1-one (5% weight reduction temperature: 170° C., i-ray absorption coefficient: 400 ml/gcm)

### (Thermal Radical Generator)

Percumyl D: manufactured by NOF Corporation, dicumyl peroxide (one-minute half-life temperature: 175° C.)

### (Coating Solvent)

NMP: manufactured by Kanto Chemical Co. Inc., N-methyl-2-pyrrolidone

TABLE 1

| | | Examples | | | | | | | | |
|---|---|---|---|---|---|---|---|---|---|---|
| | | 1 | 2 | 3 | 4 | 5 | 6 | 7 | 8 | 9 |
| (D)Thermo- | PI-1 | 10 | — | 10 | — | — | — | — | — | 10 |
| plastic resin | PI-2 | — | — | — | — | 5 | — | — | — | — |
| | PI-3 | — | — | — | — | — | 5 | — | — | — |
| (B) | YDF-8170C | — | 20 | — | 20 | 20 | 20 | — | 10 | 10 |
| Thermosetting | 630LSD | 20 | — | 20 | — | — | — | 20 | — | — |
| resin | | | | | | | | | | |
| (A)Radiation | A-BPE4 | 40 | — | 80 | — | 40 | — | — | — | — |
| polymerizable | M-140 | 40 | 80 | | 40 | 40 | 80 | 40 | 80 | — |
| compound | AMP-20GY | — | — | — | 40 | — | — | 40 | — | 20 |
| Curing | 2PZCNS- | 1 | 1 | 1 | 1 | 1 | — | 1 | 1 | 1 |
| accelerator | PW | | | | | | | | | |
| (C) Photo- | I-651 | 1 | 1 | 1 | 1 | 1 | 1 | 1 | 1 | 1 |
| initiator | | | | | | | | | | |
| Thermal radical | Percumyl D | 1 | 1 | 1 | — | 1 | 1 | 1 | 1 | 1 |
| generator | | | | | | | | | | |

| | | Comparative Examples | | | | | |
|---|---|---|---|---|---|---|---|
| | | 1 | 2 | 3 | 4 | 5 | 6 |
| (D)Thermo- | PI-1 | 5 | — | 5 | — | — | — |
| plastic resin | | | | | | | |
| (B) | YDF-8170C | 20 | 20 | 20 | 20 | 20 | — |
| Thermosetting | | | | | | | |
| resin | | | | | | | |
| (A) Radiation | A-BPE4 | 40 | — | 160 | 80 | — | — |
| polymerizale | M-140 | 40 | 80 | — | — | 40 | 80 |
| compound | AMP-20GY | — | — | — | — | 40 | — |
| Curing | 2PZCNS- | 1 | 1 | 1 | 1 | 1 | 1 |
| accelerator | PW | | | | | | |
| (C) Photo- | I-651 | 1 | 1 | 1 | 1 | — | 1 |
| initiator | | | | | | | |
| Thermal radical | Percumyl D | 1 | 1 | 1 | 1 | 1 | 1 |
| generator | | | | | | | |
| Coating solvent | NMP | 20 | 20 | — | — | — | — |

5% Weight Reduction Temperature of Adhesive Composition (After Exposure)

The adhesive composition was applied onto a silicon wafer by spin coating (2,000 rpm/10 s, 4,000 rpm/20 s), and a PET film subjected to mold-releasing treatment was laminated on the obtained coating film and exposure was performed at 1000 mJ/cm² by a high-precision parallel exposure machine (manufactured by ORC Manufacturing Co., Ltd., “EXM-1172-B-∞” (trade name)). For the adhesive composition after the exposure, its 5% weight reduction temperature was measured using a differential thermal thermogravimetry simultaneous measurement device (manufactured by SII NanoTechnology Inc., trade name “TG/DTA6300”) under the conditions of a temperature rise rate of 10° C./min and nitrogen flow (400 ml/min).

5% Weight Reduction Temperature of Adhesive Composition (After Curing)

An adhesive composition after exposure obtained in the same manner as in the above-described method was cured by heating it at 120° C. for 1 hour and then at 180° C. for 3 hours in an oven and the 5% weight reduction temperature of the cured adhesive composition was measured under the same conditions as described above.

Viscosity

The viscosity of the adhesive composition at 25° C. was measured through the use of an EHD-type rotational viscometer manufactured by Tokyo Keiki Inc.

Film Thickness

The adhesive composition was applied onto a silicon wafer by spin coating (2000 rpm/10 s, 4000 rpm/20 s) and a PET film subjected to mold-releasing treatment was laminated on the obtained coating film (adhesive layer), and exposure was performed at 1000 mJ/cm² by a high-precision parallel exposure machine (manufactured by ORC Manufacturing Co., Ltd., “EXM-1172-B-∞” (trade name)). Then, the thickness of the adhesive layer was measured through the use of a surface roughness tester (manufactured by Kosaka Laboratory Ltd.).

Thermal Compression Bonding Property (Shear Strength)

The adhesive composition was applied onto a silicon wafer by spin coating (2000 rpm/10 s, 4000 rpm/20 s), and a PET film subjected to mold-releasing treatment was laminated on the obtained coating film and exposure was performed at 1000 mJ/cm² by a high-precision parallel exposure machine (manufactured by ORC Manufacturing Co., Ltd., “EXM-1172-B-∞” (trade name)). After that, silicon chips of 3×3 mm square were cut from the silicon wafer. The cut silicon chips with the adhesive layer were placed on previously prepared silicon chips of 5×5 mm square and were compression bonded for two seconds at 120° C. while being pressurized at 100 gf. Then, they were heated in an oven at 120° C. for 1 hour and then at 180° C. for 3 hours, and samples in which the silicon chips have been made to adhere to each other were obtained. The shear strengths of the obtained samples were measured through the use of a shear strength tester “Dage-4000” (trade name) at room temperature and 260° C. The obtained measured values were used as the values of the shear strengths.

Tack Strength (Surface Tack Force)

The adhesive composition was applied onto a silicon wafer by spin coating (2,000 rpm/10 s, 4,000 rpm/20 s), and a PET film subjected to mold-releasing treatment was laminated on the obtained coating film (adhesive layer) and exposure was performed at 1000 mJ/cm² by a high-precision parallel exposure machine (manufactured by ORC Manufacturing Co., Ltd., “EXM-1172-B-∞” (trade name)). After that, the tack force of the surface of the adhesive layer at 30° C. and 120° C. was measured through the use of a probe tacking tester manufactured by Rhesca Corporation under the conditions of probe diameter of 5.1 mm, peeling speed of 10 mm/s, contact load of 100 gf/cm², and contact time of 1 s.

TABLE 2

| | | Examples | | | | | | | |
|---|---|---|---|---|---|---|---|---|---|
| | | 1 | 2 | 3 | 4 | 5 | 6 | 7 | 8 |
| Viscosity (mPa · s) | | 800 | 550 | 1200 | 200 | 650 | 800 | 500 | 850 |
| Film thickness (μm) | | 7 | 5 | 10 | 2 | 6 | 7 | 5 | 7 |
| 5% weight | After | 250 | 240 | 260 | 180 | 250 | 240 | 240 | 220 |
| reduction | exposure | | | | | | | | |
| temperature (° C.) | After heat | 360 | 350 | 380 | 260 | 360 | 350 | 350 | 300 |
| | curing | | | | | | | | |
| Surface tack force | 30° C. | 10 | 40 | 3 | 50 | 30 | 30 | 20 | 20 |
| (gf/cm²) | 120° C. | 250 | 400 | 200 | >500 | 400 | 400 | 350 | 350 |
| Shear strength | 25° C. | >10 | >10 | >10 | 8 | 7 | >10 | >10 | >10 |
| (MPa) | 260° C. | 1.4 | 1.0 | 1.2 | 0.30 | 0.20 | 0.35 | 0.70 | 0.70 |

TABLE 6

| | | Comparative Examples | | | | | |
|---|---|---|---|---|---|---|---|
| | | 1 | 2 | 3 | 4 | 5 | 6 |
| Viscosity (mPa · s) | | 150 | 100 | 1000 | 1000 | 650 | 950 |
| Film thickness (μm) | | 2 | 2 | 10 | 9 | 5 | 9 |
| 5% weight | After | <150 | <150 | 280 | 280 | 160 | 240 |
| reduction | exposure | | | | | | |
| temperature (° C.) | After heat | — | — | 350 | 350 | 260 | 260 |
| | curing | | | | | | |
| Surface tack force | 30° C. | 380 | >500 | 1.2 | 1.5 | >500 | 25 |
| (gf/cm²) | 120° C. | >500 | >500 | 1.5 | 1.8 | >500 | 250 |
| Shear strength | 25° C. | peeled | peeled | 0.5 | peeled | peeled | 2.5 |
| (MPa) | 260° C. | peeled | peeled | <0.10 | peeled | peeled | <0.10 |

### REFERENCE SIGNS LIST

1: semiconductor wafer, 2: semiconductor chip, 4: pressure sensitive adhesive tape (back grind tape), 5: adhesive composition (adhesive layer), 6: pressure sensitive adhesive tape (dicing tape), 7: supporting member, 8: grind device, 9: exposure device, 10: wafering, 11: dicing blade, 12: die bonding device, 14: heat board, 16: wire, 17: sealant, 100: semiconductor device, S1: circuit surface of semiconductor wafer, S2: rear face of semiconductor wafer

1. An adhesive composition used for adhesion of a semiconductor chip, comprising:
a radiation polymerizable compound;
a photoinitiator; and
a thermosetting resin,
wherein, when the adhesive composition forming an adhesive layer is brought to a B-stage by irradiation with light, the surface of the adhesive layer has a tack force of 200 gf/cm² or less at 30° C. and 200 gf/cm² or more at 120° C.

2. The adhesive composition according to claim 1, wherein the 5% weight reduction temperature of the adhesive composition brought to a B-stage by irradiation with light is 150° C. or more.

3. The adhesive composition according to claim 1, wherein the viscosity of the adhesive composition at 25° C. before being brought to a B-stage by irradiation with light is 10 to 30000 mPa·s.

4. The adhesive composition according to claim 1, wherein, when a semiconductor chip is made to adhere to an adherend with the adhesive composition, shear strength between the semiconductor chip and the adherend is 0.2 MPa or more at 260° C.

5. The adhesive composition according to claim 1, wherein the 5% weight reduction temperature, when the adhesive composition is brought to a B-stage by irradiation with light and then further cured by heating, is 260° C. or more.

6. The adhesive composition according to claim 1, wherein the radiation polymerizable compound includes a monofunctional (meth)acrylate.

7. The adhesive composition according to claim 1, comprising a compound having an imido group.

8. The adhesive composition according to claim 6, wherein the monofunctional (meth)acrylate includes a (meth)acrylate having an imido group.

9. A production method of a semiconductor device, comprising the steps of:
applying the adhesive composition according to claim 1 to the back surface of a semiconductor wafer;
bringing the applied adhesive composition to a B-stage by irradiation with light;
cutting the semiconductor wafer together with the adhesive composition brought to the B-stage into a plurality of semiconductor chips; and
making the semiconductor chip to adhere to a supporting member or another semiconductor chip by performing compression bonding, with the adhesive composition therebetween.

10. A semiconductor device obtainable by the production method according to claim 9.
